(19) United States
(12) Patent Application Publication
(10) Pub. No.: US 2026/0020312 A1
(43) Pub. Date: Jan. 15, 2026

(54) SEMICONDUCTOR DEVICE

(71) Applicant: SAMSUNG ELECTRONICS CO., LTD., Suwon-si (KR)

(72) Inventors: Dong Woo Kim, Suwon-si (KR); Chul Sung Kim, Suwon-si (KR); Dong Hyun Roh, Suwon-si (KR); Tae-Yeon Shin, Suwon-si (KR); Bok Young Lee, Suwon-si (KR)

(21) Appl. No.: 19/049,844

(22) Filed: Feb. 10, 2025

(30) Foreign Application Priority Data
Jul. 9, 2024 (KR) 10-2024-0090243

(51) Int. Cl. H10D 64/23; H10D 30/00; H10D 30/01

(52) U.S. Cl. CPC H10D 64/254; H10D 30/0198; H10D 30/501

(57) ABSTRACT

A semiconductor device includes a back interlayer insulating film, a back wiring line within the back interlayer insulating film, a first source/drain pattern on the back wiring line, a second source/drain pattern on the back wiring line and spaced apart from the first source/drain pattern, and a back source/drain contact between the first source/drain pattern and the back wiring line, connected to the first source/drain pattern, and overlapping with the first source/drain pattern. The back source/drain contact is connected to the first source/drain pattern and, in a cross-sectional view cut perpendicular to a third direction, a first surface of the back source/drain contact has a convex shape, and in a cross-sectional view cut perpendicular to a second direction, the first surface of the back source/drain contact has a concave shape.

### CROSS-REFERENCE TO RELATED APPLICATION

This application claims priority from Korean Patent Application No. 10-2024-0090243 filed on Jul. 9, 2024, in the Korean Intellectual Property Office, and all the benefits accruing therefrom under 35 U.S.C. 119, the contents of which in its entirety are herein incorporated by reference.

### BACKGROUND

As one of the scaling technologies to increase the density of semiconductor devices, multi-gate transistors have been proposed. The multi-gate transistors are obtained by forming multi-channel active patterns (or silicon bodies) in the shape of fins or nanowires on a substrate and then forming gates on the surfaces of the multi-channel active patterns.

The multi-gate transistors are easier to scale due to their utilization of three-dimensional (3D) channels. Additionally, the multi-gate transistors can improve current control capabilities without increasing their gate length. Moreover, the multi-gate transistors can effectively suppress the short channel effect (SCE), where the potential in a channel area is affected by the drain voltage.

### SUMMARY

Aspects of the present disclosure provide a semiconductor device that can improve device performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Meanwhile, as the pitch size of semiconductor devices decreases, research is needed to reduce parasitic capacitance and ensure electrical stability between contacts within a semiconductor device.

According to an aspect of the present disclosure, there is provided a semiconductor device comprising, a back interlayer insulating film, a back wiring line within the back interlayer insulating film, and including a first surface and a second surface that are opposite to each other in a first direction, a first source/drain pattern on the first surface of the back wiring line, a second source/drain pattern on the first surface of the back wiring line and spaced apart from the first source/drain pattern in a second direction that is different from the first direction, and a back source/drain contact between the first source/drain pattern and the back wiring line, wherein the back source/drain contact is connected to the first source/drain pattern and overlaps with the first source/drain pattern in the first direction, wherein the back source/drain contact includes a first surface that is connected to the first source/drain pattern and a second surface that is opposite to the first surface in the first direction, wherein, the first surface of the back source/drain contact has a convex shape extending along the second direction, and wherein, the first surface of the back source/drain contact has a concave shape extending along a third direction that is different from the first and second directions.

According to an aspect of the present disclosure, there is provided a semiconductor device comprising, a back interlayer insulating film, a back wiring line within the back interlayer insulating film, and including a first surface and a second surface that are opposite to each other in a first direction, a first source/drain pattern on the first surface of the back wiring line, a second source/drain pattern on the first surface of the back wiring line and spaced apart from the first source/drain pattern in a second direction, and a back source/drain contact between the first source/drain pattern and the back wiring line, wherein the back source/drain contact is connected to the first source/drain pattern and overlaps with the first source/drain pattern in the first direction, wherein the back source/drain contact includes a first surface that is connected to the first source/drain pattern and a second surface that is opposite to the first surface in the first direction, and the first surface of the back source/drain contact includes a saddle point.

According to an aspect of the present disclosure, there is provided a semiconductor device comprising, a back interlayer insulating film, a back wiring line within the back interlayer insulating film, wherein the back wiring line includes a first surface and a second surface that are opposite to each other in a first direction, a first source/drain pattern on the first surface of the back wiring line, a second source/drain pattern on the first surface of the back wiring line and spaced apart from the first source/drain pattern in a second direction, wherein the second direction is different from the first direction, a plurality of sheet patterns connected to the first source/drain pattern and the second source/drain pattern, a gate electrode surrounding the plurality of sheet patterns and extending in a third direction, a back source/drain contact between the first source/drain pattern and the back wiring line and connected to the first source/drain pattern, and a back contact silicide film between the back source/drain contact and the first source/drain pattern, wherein the back source/drain contact includes a connection surface in contact with the back contact silicide film, and the connection surface of the back source/drain contact has a three-dimensional saddle structure.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary implementations thereof with reference to the attached drawings, in which:

FIG. 1 is a layout diagram for explaining a semiconductor device according to some implementations of the present disclosure.

FIG. 2 is a cross-sectional view along line A-A in FIG. 1.

FIG. 3 is a cross-sectional view along line B-B in FIG. 1.

FIG. 4 is a cross-sectional view along line C-C in FIG. 1.

FIG. 5 is a cross-sectional view cut along line D-D of FIG. 1.

FIG. 6 is a diagram for explaining the 3D shape of a first back source/drain contact of FIG. 1.

FIG. 7 is diagram for explaining semiconductor device according to some implementations of the present disclosure.

FIGS. 8 and 9 are diagrams for explaining semiconductor device according to some implementations of the present disclosure.

FIGS. 10 to 12 are diagrams for explaining semiconductor device according to some implementations of the present disclosure.

FIGS. 13 and 14 are diagrams for explaining semiconductor device according to some implementations of the present disclosure.

FIGS. 15 and 16 are diagrams for explaining semiconductor device according to some implementations of the present disclosure.

FIGS. 17 to 19 are diagrams for explaining semiconductor device according to some implementations of the present disclosure.

FIG. 20 is diagram for explaining semiconductor device according to some implementations of the present disclosure.

FIGS. 21 to 33 are diagrams for explaining intermediate steps of a method of manufacturing a semiconductor device according to some implementations of the present disclosure.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the accompanying drawings related to semiconductor devices according to some implementations of the present disclosure, various types of transistors are exemplified, including transistors containing nanowires or nanosheets or Multi-Bridge Channel Field Effect Transistors (MBCFETs™), but the present disclosure is not limited thereto. The semiconductor devices according to some implementations of the present disclosure may also be applicable to Fin Field-Effect Transistors (FinFETs) with fin-shaped patterned channel areas.

The semiconductor devices according to some implementations of the present disclosure may include tunneling Field-Effect Transistors (FETs), three-dimensional (3D) transistors, or vertical FETs, and may also include planar transistors. Additionally, the technical concept of the present disclosure can be applied to transistors based on two-dimensional (2D) materials and their heterostructures. Furthermore, the semiconductor devices according to some implementations of the present disclosure may also include bipolar junction transistors and Lateral Diffused Metal Oxide Semiconductor (LDMOS) transistors.

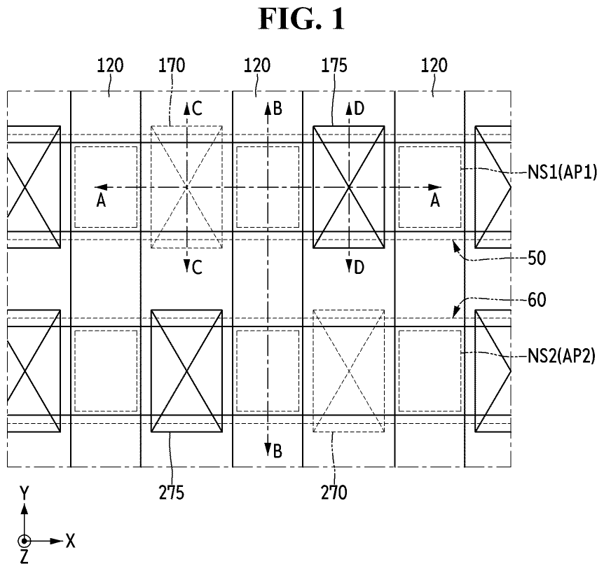

A semiconductor device according to some implementations of the present disclosure will hereinafter be described with reference to FIGS. 1 through 6.

FIG. 1 is a layout diagram for explaining a semiconductor device according to some

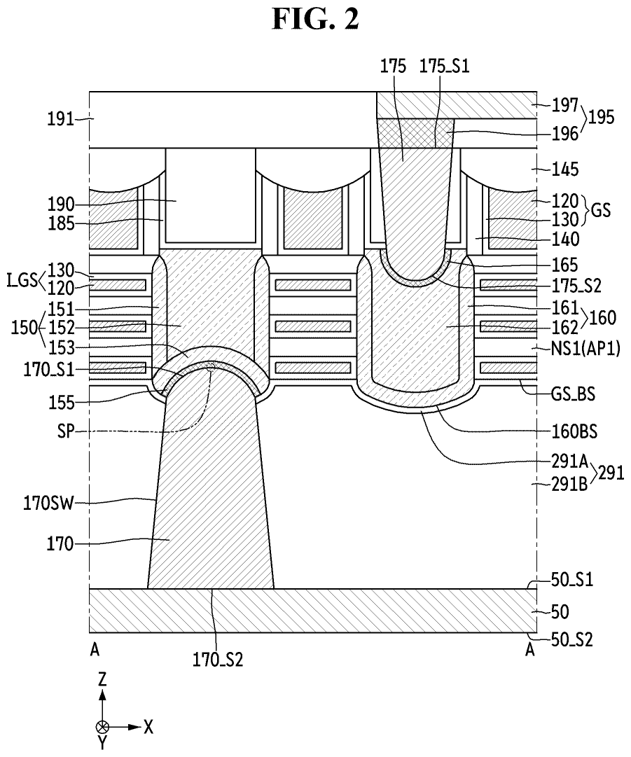

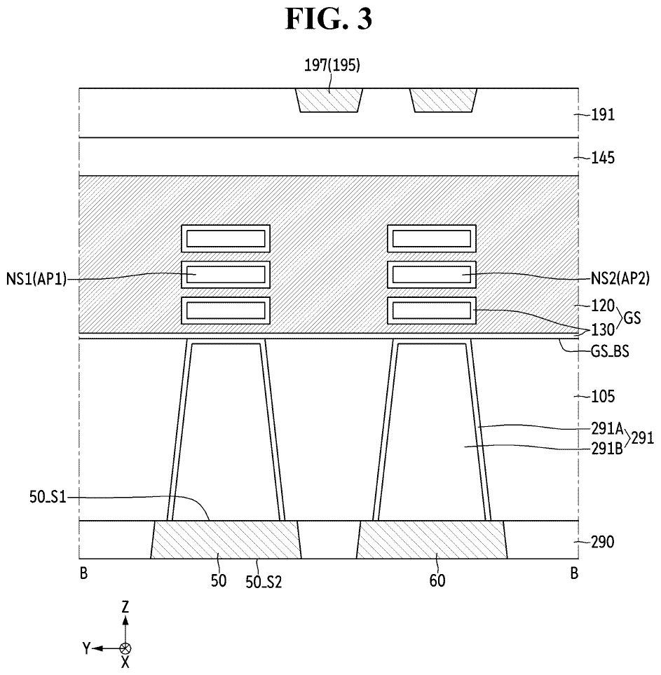

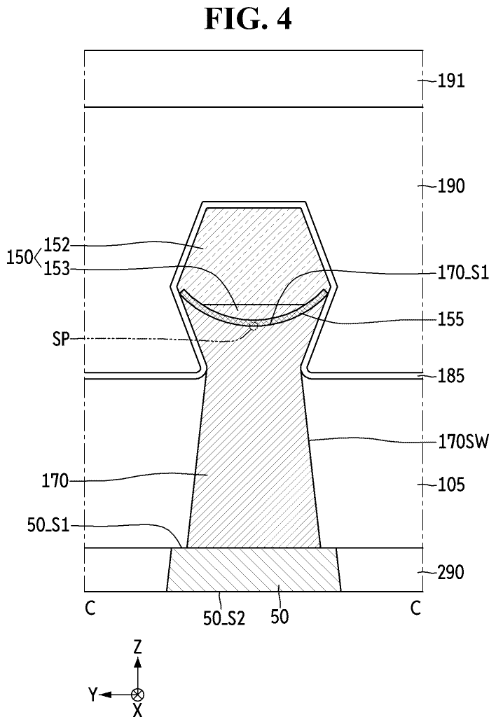

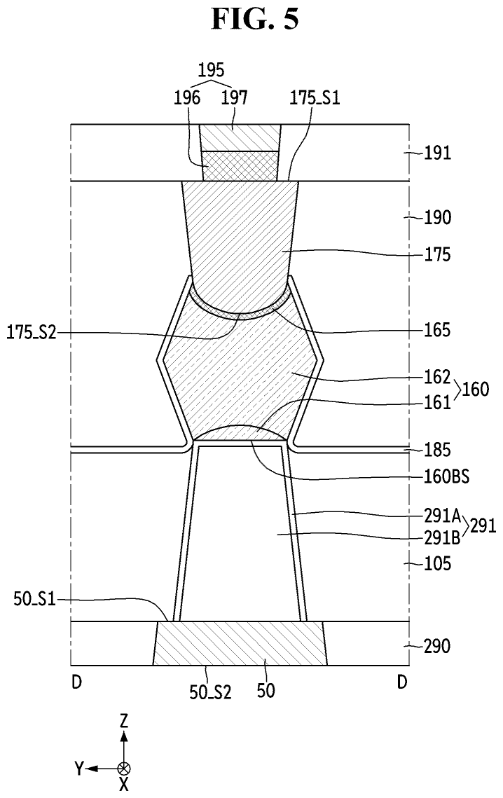

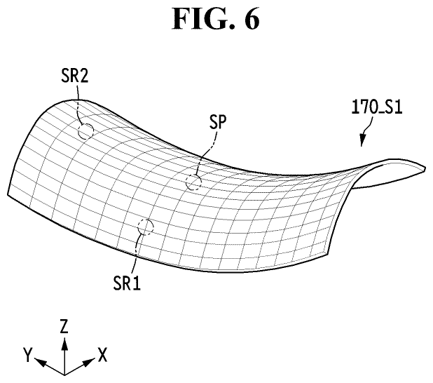

implementations of the present disclosure. FIG. 2 is a cross-sectional view along line A-A in FIG. 1. FIG. 3 is a cross-sectional view along line B-B in FIG. 1. FIG. 4 is a cross-sectional view along line C-C in FIG. 1. FIG. 5 is a cross-sectional view cut along line D-D of FIG. 1. FIG. 6 is a diagram for explaining the 3D shape of a first back source/drain contact of FIG. 1. For convenience, a front wiring structure 195 is not illustrated in FIG. 1.

A cross-sectional view taken across the part where second sheet patterns NS2 are disposed in a first direction X may be similar to what is illustrated in FIG. 2.

Referring to FIGS. 1 to 6, the semiconductor device according to some implementations of the present disclosure may include a first active pattern AP1, a second active pattern AP2, a plurality of gate electrodes 120, a first source/drain pattern 150, a second source/drain pattern 160, a first back source/drain contact 170, a second back source/drain contact 270, a first front source/drain contact 175, a second front source/drain contact 275, a first back wiring line 50, a second back wiring line 60, and the front wiring structure 195.

The first and second back wiring lines 50 and 60 may be disposed within a back interlayer insulating film 290. The first and second back wiring lines 50 and 60 may extend in the first direction X. The first back wiring line 50 may be spaced apart from the second back wiring line 60 in a second direction Y.

For example, the first and second back wiring lines 50 and 60 may serve as power lines supplying power to the semiconductor device according to some implementations of the present disclosure. In another example, the first and second back wiring lines 50 and 60 may function as signal lines delivering operational signals to the semiconductor device according to some implementations of the present disclosure. In yet another example, one of the first and second back wiring lines 50 and 60 may be a power line, and the other back wiring line may be a signal line.

The first back wiring line 50 may have a first surface 50_S1 and a second surface 50_S2 that are opposite to each other in a third direction Z. The second back wiring line 60 may have first and second surfaces that are opposite to each other in the third direction Z. The first surface 50_S1 of the first back wiring line 50 and the first surface of the second back wiring line 60 may face the first active pattern AP1 and the second active pattern AP2, respectively. Here, the first direction X may intersect the second and third directions Y and Z. Moreover, the second direction Y may intersect the third direction Z.

The first back wiring line 50 and the second back wiring line 60 are illustrated as having a trapezoidal cross-sectional shape, but the present disclosure is not limited thereto. Alternatively, the first back wiring line 50 and the second back wiring line 60 may have a rectangular cross-sectional shape. For example, the width, in the second direction Y, of the first surface 50_S1 of the first back wiring line 50 may be less than the width, in the second direction Y, of the second surface 50_S2 of the first back wiring line 50.

For example, the first back wiring line 50 and the second back wiring line 60 may be formed by a damascene process. The first back wiring line 50 may be formed by forming a trench that extends in the first direction X, in the first back interlayer insulating film 290 and filling the trench with a conductive material.

The first back wiring line 50 and the second back wiring line 60 are illustrated as having a single conductive film structure, but the present disclosure is not limited thereto. Alternatively the first back wiring line 50 and the second back wiring line 60 may each have a multilayer conductive film structure including a wiring barrier film and a wiring filling film. In this case, the wiring filling film may fill a wiring filling film trench defined by the wiring barrier film.

The first back wiring line 50 and the second back wiring line 60 may include, for example, at least one of a metal, a conductive metal nitride, a conductive metal carbide, a conductive metal oxide, a conductive metal carbonitride, and a 2D material. The 2D material may include a 2D allotrope or compound. Examples of the 2D material include at least one of graphene, boron nitride (BN), molybdenum sulfide, molybdenum selenide, tungsten sulfide, tungsten selenide, and tantalum sulfide, but the present disclosure is not limited thereto. That is, the 2D material is not particularly limited.

The first back wiring line 50 and the second back wiring line 60 may extend in the second direction Y. In this case, the cross-sectional shapes, along lines A-A, B-B, C-C, and D-D in FIG. 1, of the first back wiring line 50 and the second back wiring line 60 may change.

The first back wiring line 50 and the second back wiring line 60 may include linear portions and via portions. For example, the linear portion of the first back wiring line 50 may extend longitudinally in the first direction X, and the via portion of the first back wiring line 50 may protrude in the third direction Z from the linear portion of the first back wiring line 50. The via portion of the first back wiring line 50 may protrude toward the first back source/drain contact 170.

The back interlayer insulating film 290 may include, for example, at least one of silicon oxide, silicon nitride, silicon carbonitride, silicon oxynitride, and a low-k material. The dielectric constant of the low-k material may be lower than 3.9, which is the dielectric constant of silicon oxide. The back interlayer insulating film 290 is illustrated as being a single layer, but the present disclosure is not limited thereto.

A back insert insulating film 291 may be disposed on the back interlayer insulating film 290. The back insert insulating film 291 may be disposed on the first surface 50_S1 of the first back wiring line 50.

In the semiconductor device according to some implementations of the present disclosure, the back insert insulating film 291 may be disposed between the back interlayer insulating film 290 and the first active pattern AP1, and between the back interlayer insulating film 290 and the second active pattern AP2. The back insert insulating film 291 may be disposed between the back interlayer insulating film 290 and the first source/drain pattern 150, and between the back interlayer insulating film 290 and the second source/drain pattern 160.

The back insert insulating film 291 may extend in the first direction X. The back insert insulating film 291 may have upper and bottom surfaces that are opposite to each other in the third direction Z. The bottom surface of the back insert insulating film 291 may face the first back wiring line 50 and the second back wiring line 60.

In the semiconductor device according to some implementations of the present disclosure, the upper surface of the back insert insulating film 291 may have a corrugated shape from a cross-sectional perspective. For example, the upper surface of the back insert insulating film 291 may include concave portions and convex portions. The concave portions of the upper surface of the back insert insulating film 291 may overlap with the first source/drain pattern 150 and the second source/drain pattern 160 in the third direction Z. The convex portions of the upper surface of the back insert insulating film 291 may overlap with gate structure GS in the third direction Z.

For example, the back insert insulating film 291 may contact the gate structures GS. The back insert insulating film 291 may contact the first source/drain pattern 150 and the second source/drain pattern 160.

The back insert insulating film 291 may include a back insert liner 291A and a back insert filling layer 291B. In a cross-sectional view such as FIG. 2, the back insert liner 291A may extend along bottom surfaces GS_BS of the gate structures GS, the first source/drain pattern 150, and the second source/drain pattern 160. In the semiconductor device according to some implementations of the present disclosure, the back insert liner 291A may contact the bottom surfaces GS_BS of the gate structures GS, the first source/drain pattern 150, and the second source/drain pattern 160.

The back insert filling layer 291B may be disposed on the back insert liner 291A.

The back insert filling layer 291B may fill the trench defined by the back insert liner 291A. In a cross-sectional view such as FIG. 3, the back insert liner 291A may be disposed between a field insulating film 105 and the back insert filling layer 291B, and between the gate structures GS and the back insert filling layer 291B.

Each of the back insert liner 291A and the back insert filling layer 291B may include an insulating material. For example, each of the back insert liner 291A and the back insert filling layer 291B may include at least one of silicon nitride, silicon oxynitride, silicon oxide, silicon boronitride, silicon boronoxynitride, silicon carbonitride, silicon oxycarbide, and a low-k dielectric material.

The back insert insulating film 291 is illustrated as having a multilayer structure, but the present disclosure is not limited thereto. Alternatively, the back insert insulating film 291 may be a single layer.

The field insulating film 105 may be disposed on the first back wiring line 50 and the second back wiring line 60. For example, the field insulating film 105 may be disposed on the first surface 50_S1 of the first back wiring line 50 and on the first surface of the second back wiring line 60.

The back insert insulating film 291 may have sidewalls connecting the upper surface and the bottom surface of the back insert insulating film 291. The field insulating film 105 may be disposed on the sidewalls of the back insert insulating film 291. The field insulating film 105 may cover the sidewalls of the back insert insulating film 291.

The field insulating film 105 may include at least one of silicon oxide, silicon nitride, silicon oxynitride, and a low-k dielectric material. The field insulating film 105 is illustrated as being a single layer, but the present disclosure is not limited thereto.

When the back insert insulating film 291 and the field insulating film 105 are single layers and include the same insulating material, the interface between the back insert insulating film 291 and the field insulating film 105 may not be distinguishable in a cross-sectional view such as FIGS. 3 and 5. In this case, the portion overlapping with the active patterns (AP1 and AP2) in the third direction Z may be the back insert insulating film 291. Alternatively, the portion overlapping with the second source/drain pattern 160 in the third direction Z may be the back insert insulating film 291.

The first active pattern AP1 and the second active pattern AP2 may be disposed on the first surface 50_S1 of the first back wiring line 50 and on the first surface of the second back wiring line 60. The first surface 50_S1 of the first back wiring line 50 and the first surface of the second back wiring line 60 may face the first active pattern AP1 and the second active pattern AP2.

The first active pattern AP1 and the second active pattern AP2 may be disposed on the back insert insulating film 291. The first active pattern AP1 and the second active pattern AP2 may be disposed on the upper surface of the back insert insulating film 291.

The first active pattern AP1 and the second active pattern AP2 may be spaced apart in the second direction Y. The first active pattern AP1 and the second active pattern AP2 may be adjacent to each other in the second direction Y.

The first active pattern AP1 is illustrated as being closest to the second active pattern AP2 in the second direction Y, but the present disclosure is not limited thereto. Additional active patterns may be disposed between the first active pattern AP1 and the second active pattern AP2.

For example, the first active pattern AP1 may be a region where p-type transistors are formed, and the second active pattern AP2 may be a region where n-type transistors are formed. In another example, both the first active pattern AP1 and the second active pattern AP2 may be regions where p-type transistors are formed. In yet another example, both the first active pattern AP1 and the second active pattern AP2 may be regions where n-type transistors are formed.

The first active pattern AP1 and the second active pattern AP2 may be multi-channel active patterns. The first active pattern AP1 may include a plurality of first sheet patterns NS1. The second active pattern AP2 may include a plurality of second sheet patterns NS2. In the semiconductor device according to some implementations of the present disclosure, the first active pattern AP1 and the second active pattern AP2 may be active patterns including nano sheets and nano wires.

A plurality of first sheet patterns NS1 may be disposed on the back insert insulating film 291. The first sheet patterns NS1 may be spaced apart from the back insert insulating film 291 in the third direction Z. Each of the first sheet patterns NS1 may have top and bottom surfaces that are opposite to each other in the third direction Z. The bottom surfaces of the first sheet patterns NS1 may face the back insert insulating film 291. Each of the first sheet patterns NS1 may have a first end and a second end. The first ends of the first sheet patterns NS1 may be spaced apart from the second ends of the first sheet patterns NS1 in the first direction X. The first ends and second ends of the first sheet patterns NS1 may be connected to the first source/drain pattern 150 and the second source/drain pattern 160, respectively, which will be described later.

A plurality of second sheet patterns NS2 may be disposed on the back insert insulating film 291. The second sheet patterns NS2 may be spaced apart from the back insert insulating film 291 in the third direction Z. Each of the second sheet patterns NS2 may include top and bottom surfaces that are opposite to each other in the third direction Z. The bottom surfaces of the second sheet patterns NS2 may face the back insert insulating film 291.

Three first sheet patterns NS1 and three second sheet patterns NS2 may be arranged in the third direction Z, but the present disclosure is not limited thereto.

The first sheet patterns NS1 and the second sheet patterns NS2 may each include an elemental semiconductor material such as silicon (Si) or germanium (Ge). Alternatively, the first sheet patterns NS1 and the second sheet patterns NS2 may each include a compound semiconductor, for example, a group IV-IV compound semiconductor or a group III-V compound semiconductor.

The group IV-IV compound semiconductor may include, for example, a binary, ternary, or quaternary compound containing at least two of carbon (C), Si, Ge, and tin (Sn), or a compound obtained by doping this binary, ternary, or quaternary compound with a group IV element.

The group III-V compound semiconductor may include, for example, a binary, ternary, or quaternary compound formed by combining at least one of aluminum (Al), gallium (Ga), and indium (In), which are group III elements, with one of phosphorus (P), arsenic (As), and antimony (Sb), which are group V elements.

The first sheet patterns NS1 are illustrated as having the same width, but the present disclosure is not limited thereto. The width of the first sheet patterns NS1 may increase or decrease proportionally to the width, in the second direction Y, of the back insert insulating film 291. The description of the width of the second sheet patterns NS2 may be substantially the same as the description of the width of the first sheet patterns NS1.

A plurality of gate structures GS may be disposed on the field insulating film 105 and the back insert insulating film 291. The gate structures GS may be disposed on the first surface 50_S1 of the first back wiring line 50 and on the first surface of the second back wiring line 60.

The back insert insulating film 291 may be disposed between the gate structures GS and the first back wiring line 50. The back insert insulating film 291 may be disposed between the gate structures GS and the second back wiring line 60.

The gate structures GS may extend in the second direction Y. The gate structures GS may be spaced apart in the first direction X. The gate structures GS may be adjacent to each other in the first direction X. The gate structures GS may intersect the back insert insulating film 291.

The gate structures GS may surround each of the first sheet patterns NS1. The gate structures GS may surround each of the second sheet patterns NS2.

The gate structures GS are illustrated as being disposed across the first active pattern AP1 and the second active pattern AP2, but the present disclosure is not limited thereto. That is, some of the gate structures GS may be divided into first parts and second parts by gate isolation structures disposed on the field insulating film 105. In this case, the first parts of the gate structure GS may surround the first sheet patterns NS1, and the second parts of the gate structures GS may surround the second sheet patterns NS2.

Each of the gate structures GS may have a bottom surface GS_BS and an upper surface that are opposite to each other in the third direction Z. The bottom surfaces GS_BS of the gate structures GS may face the first back wiring line 50 and the second back wiring line 60.

In the semiconductor device according to some implementations of the present disclosure, the gate structures GS may contact the back insert insulating film 291. For example, the back insert insulating film 291 may contact the bottom surfaces GS_BS of the gate structures GS.

The gate structures GS may include, for example, the gate electrodes 120 and the gate insulating film 130.

The gate structures GS may include a plurality of inner gate structures I_GS, which are disposed between each pair of adjacent first sheet patterns NS1 in the third direction Z, and between the back insert insulating film 291 and the first sheet patterns NS1. The inner gate structures I_GS may be disposed between the upper surface of the back insert insulating film 291 and the bottom surfaces of the first sheet patterns NS1, and between the upper surfaces and the bottom surfaces of the first sheet patterns NS1 that face each other in the third direction Z. The inner gate structures I_GS may include the gate electrodes 120 and the gate insulating film 130.

The number of inner gate structures I_GS may be the same as the number of first sheet patterns NS1. The inner gate structures I_GS may contact the upper surfaces and the bottom surfaces of the first sheet patterns NS1.

In the semiconductor device according to some implementations of the present disclosure, the inner gate structures I_GS may contact the upper surface of the back insert insulating film 291. The inner gate structures I_GS may contact the first source/drain pattern 150 and the second source/drain pattern 160, which will be described later.

The inner gate structures I_GS may be disposed between each pair of adjacent second sheet patterns NS2 in the third direction Z, and between the back insert insulating film 291 and the second sheet patterns NS2.

The gate electrodes 120 may be disposed on the back insert insulating film 291. The gate electrodes 120 may intersect the back insert insulating film 291. The gate electrodes 120 may surround the first sheet patterns NS1 and the second sheet patterns NS2.

In a cross-sectional view such as FIG. 2, the upper surfaces of the gate electrodes 120 are illustrated as being concave surfaces, but the present disclosure is not limited thereto. Alternatively, the upper surfaces of the gate electrodes 120 may be flat.

The gate electrodes 120 may include at least one of a metal, a metal alloy, a conductive metal nitride, a metal silicide, a doped semiconductor material, a conductive metal oxide, and a conductive metal oxynitride. The first gate electrodes 120 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. Here, the conductive metal oxide and conductive metal oxynitride may include oxidized forms of the aforementioned materials, but the present disclosure is not limited thereto.

The gate insulating film 130 may extend along the upper surface of the field insulating film 105 and the upper surface of the back insert insulating film 291. The gate insulating film 130 may surround the first sheet patterns NS1. The gate insulating film 130 may surround the second sheet patterns NS2. The gate insulating film 130 may be disposed along the circumferences of the first sheet patterns NS1 and the circumferences of the second sheet patterns NS2. The first gate electrodes 120 may be disposed on the gate insulating film 130.

The gate insulating film 130 may be disposed between the first gate electrodes 120 and the first sheet patterns NS1, and between the first gate electrodes 120 and the second sheet patterns NS2. For example, the gate insulating film 130 may contact the back insert insulating film 291. In the semiconductor device according to some implementations of the present disclosure, the gate insulating film 130 included in the first inner gate structures I_GS1 may contact the first source/drain pattern 150 and the second source/drain pattern 160, which will be described later.

The gate insulating film 130 may include silicon oxide, silicon oxynitride, silicon nitride, or a high-k dielectric material that has a higher dielectric constant than silicon oxide. The high-k dielectric material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate insulating film 130 is illustrated as being a single layer, but the present disclosure is not limited thereto. The gate insulating film 130 may include multiple films. The gate insulating film 130 may include an interfacial film and a high-k insulating film disposed between the first sheet patterns NS1 and the first gate electrodes 120, and between the second sheet patterns NS2 and the first gate electrodes 120. For example, the interfacial films may not be formed along the profile of the upper surface of the field insulating film 105.

The semiconductor device according to some implementations of the present disclosure may include a negative capacitance (NC) FET utilizing a negative capacitor. For example, the gate insulating film 130 may include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one of hafnium oxide, hafnium zirconium oxide, barium strontium titanium oxide, barium titanium oxide, and lead zirconium titanium oxide. Here, the hafnium zirconium oxide may be, for example, a material obtained by doping hafnium oxide with zirconium (Zr). Alternatively, the hafnium zirconium oxide may be the compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one of Gd, Si, Zr, Al, and Y.

If the dopant is Al, the ferroelectric material film may contain 3 to 8 atomic % (at %) of Al. Here, the proportion of the dopant may be the ratio of Al to the sum of Hf and Al.

If the dopant is Si, the ferroelectric material film may contain 2 to 10 at % of Si. If the dopant is Y, the ferroelectric material film may contain 2 to 10 at % of Y. If the dopant is Gd, the ferroelectric material film may contain 1 to 7 at % of Gd. If the dopant is Zr, the ferroelectric material film may contain 50 to 80 at % of Zr.

The paraelectric material film may have paraelectric properties. For example, the paraelectric material film may include at least one of silicon oxide and a high-k metal oxide. The high-k metal oxide may include at least one of hafnium oxide, zirconium oxide, and aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the present disclosure is not limited thereto. Since the critical thickness for exhibiting ferroelectric properties may vary from one ferroelectric material to another, the thickness of the ferroelectric material film may vary depending on its material.

For example, the gate insulating film 130 may include one ferroelectric material film. Alternatively, the gate insulating film 130 may include a plurality of ferroelectric material films that are spaced apart from one another. The gate insulating film 130 may have a layered film structure in which a plurality of ferroelectric material films and a plurality of paraelectric material films are alternately stacked.

Gate spacers 140 may be disposed on the sidewalls of the gate structures GS. The gate spacers 140 may not be disposed between the back insert insulating film 291 and the first sheet patterns NS1, and between each pair of adjacent first sheet patterns NS1 in the third direction Z.

The gate spacers 140 may include, for example, at least one of silicon nitride (SiN), silicon oxynitride (SiON), silicon dioxide (SiO₂), silicon oxycarbonitride (SiOCN), silicon boron nitride (SiBN), silicon oxyboron nitride (SiOBN), silicon oxycarbide (SiOC), and a combination thereof. The gate spacers 140 are illustrated as being single layers, but the present disclosure is not limited thereto.

Gate capping patterns 145 may be disposed on the first gate electrodes 120. The upper surfaces of the gate capping patterns 145 may be on the same plane as the upper surface of a first front interlayer insulating film 190. Alternatively, the gate capping patterns 145 may be disposed between the gate spacers 140.

The gate capping patterns 145 may include, for example, at least one of SiN, SiON, silicon carbonitride (SiCN), SiOCN, and a combination thereof. The gate capping patterns 145 may include a material that has an etch selectivity relative to the first front interlayer insulating film 190.

The first source/drain pattern 150 may be disposed on the back insert insulating film 291. The first source/drain pattern 150 may be disposed between each pair of adjacent first gate electrodes 120 in the first direction X. The first source/drain pattern 150 may be disposed on sides of the first gate electrodes 120.

The first source/drain pattern 150 may contact the first sheet patterns NS1. The first source/drain pattern 150 may be disposed on the first surface 50_S1 of the first back wiring line 50 and on the first surface of the second back wiring line 60. The first source/drain pattern 150 may be connected to the first ends of the first sheet patterns NS1.

The second source/drain pattern 160 may be disposed on the back insert insulating film 291. The second source/drain pattern 160 may be disposed between each pair of adjacent gate electrodes 120 in the first direction X. The second source/drain pattern 160 may be disposed on the sides of the gate electrodes 120. The second source/drain pattern 160 may be spaced apart from the first source/drain pattern 150 in the first direction X.

The gate electrodes 120 may be disposed between the first source/drain pattern 150 and the second source/drain pattern 160. The first source/drain pattern 150 may be disposed on one side of the respective gate electrodes 120, and the second source/drain pattern 160 may be disposed on the other side of the respective gate electrodes 120.

The second source/drain pattern 160 may contact the first sheet patterns NS1. The second source/drain pattern 160 may be disposed on the first surface 50_S1 of the first back wiring line 50 and on the first surface of the second back wiring line 60. The second source/drain pattern 160 may be connected to the second ends of the first sheet patterns NS1.

In the semiconductor device according to some implementations of the present disclosure, the first source/drain pattern 150 and the second source/drain pattern 160 may contact the back insert insulating film 291. The bottom surfaces of the first source/drain pattern 150 and bottom surfaces 160BS of the second source/drain pattern 160 may contact the back insert insulating film 291.

Source/drain patterns may be disposed on both sides of the second sheet patterns NS2.

The first source/drain pattern 150 and the second source/drain pattern 160 may be included in the sources/drains of transistors using the first sheet patterns NS1 as channel regions.

The first source/drain pattern 150 and the second source/drain pattern 160 may each include epitaxial patterns. The first source/drain pattern 150 and the second source/drain pattern 160 may each include a semiconductor material.

The first source/drain pattern 150 and the second source/drain pattern 160 may each include, for example, an elemental semiconductor material such as Si or Ge. Additionally, the first source/drain pattern 150 and the second source/drain pattern 160 may each include a binary or ternary compound containing at least two of C, Si, Ge, and Sn, or a compound obtained by doping this binary or tertiary compound with a Group IV element. The first source/drain pattern 150 and the second source/drain pattern 160 may each include an epitaxial film formed of a semiconductor material.

The first source/drain pattern 150 and the second source/drain pattern 160 may each include a dopant doped into the semiconductor material. The first source/drain pattern 150 and the second source/drain pattern 160 include dopants of the same conductivity type.

In one example, the first source/drain pattern 150 and the second source/drain pattern 160 may each include a p-type dopant. The p-type dopant may include at least one of boron (B) and Ga, but the present disclosure is not limited thereto.

In another example, the first source/drain pattern 150 and the second source/drain pattern 160 may each include an n-type dopant. The n-type dopants may include at least one of P, As, Sb, and bismuth (Bi), but the present disclosure is not limited thereto.

Each of the first source/drain pattern 150 may include first semiconductor liners 151, a first semiconductor filling film 152, and a first semiconductor bottom film 153. The first semiconductor filling film 152 may be disposed on the first semiconductor liners 151 and the first semiconductor bottom film 153. From a cross-sectional perspective as illustrated in FIG. 2, the first semiconductor filling film 152 may be disposed between the first semiconductor liners 151 that are spaced apart in the first direction X. The first semiconductor bottom film 153 may be included in the source/drain patterns to be connected to the first back source/drain contact 170 described later.

Each of the second source/drain pattern 160 may include a second semiconductor liner 161 and a second semiconductor filling film 162. The second semiconductor filling film 162 may be disposed on the second semiconductor liner 161.

In one example, the first source/drain pattern 150 and the second source/drain pattern 160 may be included in the sources/drains of p-type transistors. The first source/drain pattern 150 and the second source/drain pattern 160 may each include a p-type dopant. For example, the first semiconductor liners 151, the first semiconductor filling film 152, the first semiconductor bottom film 153, the second semiconductor liner 161, and the second semiconductor filling film 162 may each include silicon-germanium (SiGe), but the present disclosure is not limited thereto.

The Ge fraction in the first semiconductor filling film 152 may be greater than the Ge fraction in the first semiconductor liners 151. The Ge fraction in the first semiconductor bottom film 153 may be greater than the Ge fraction in the first semiconductor liners 151. The concentration of the p-type dopant in the first semiconductor filling film 152 may be greater than the concentration of the p-type dopant in the first semiconductor liners 151. The concentration of the p-type dopant in the first semiconductor bottom film 153 may be greater than the concentration of the p-type dopant in the first semiconductor liners 151.

The Ge fraction in the second semiconductor filling film 162 may be greater than the Ge fraction in the second semiconductor liner 161. The concentration of the p-type dopant in the second semiconductor filling film 162 may be greater than the concentration of the p-type dopant in the second semiconductor liner 161.

In another example, the first source/drain pattern 150 and the second source/drain pattern 160 may be included in the sources/drains of n-type transistors. The first source/drain pattern 150 and the second source/drain pattern 160 may each include an n-type dopant. For example, the first semiconductor liners 151, the first semiconductor filling film 152, the first semiconductor bottom film 153, the second semiconductor liner 161, and the second semiconductor filling film 162 may each include silicon, but the present disclosure is not limited thereto.

The concentration of the n-type dopant in the first semiconductor filling film 152 may be greater than the concentration of the n-type dopant in the first semiconductor liners 151. The concentration of the n-type dopant in the first semiconductor bottom film 153 may be greater than the concentration of the n-type dopant in the first semiconductor liners 151. The n-type dopant in the first semiconductor filling film 152 may be different from or the same as the n-type dopant in the first semiconductor liners 151. The n-type dopant in the first semiconductor bottom film 153 may be different from or the same as the n-type dopant in the first semiconductor liners 151.

The concentration of n-type dopants in the second semiconductor filling film 162 may be greater than the concentration of n-type dopants in the second semiconductor liner 161. The n-type dopants in the second semiconductor filling film 162 may be different from or the same as the n-type dopants in the second semiconductor liner 161.

In FIGS. 4 and 5, the first source/drain pattern 150 and the second source/drain pattern 160 are illustrated as having a similar shape to a hexagon, but the present disclosure is not limited thereto. Alternatively, the first source/drain pattern 150 and the second source/drain pattern 160 may have a similar shape to a pentagon or quadrilateral.

The first front interlayer insulating film 190 is disposed on the back insert insulating film 291 and the field insulating film 105. The first front interlayer insulating film 190 may be disposed on the first source/drain pattern 150 and the second source/drain pattern 160. The first front interlayer insulating film 190 may not cover the upper surfaces of the gate capping patterns 145. For example, the upper surface of the first front interlayer insulating film 190 may be on the same plane as the upper surfaces of the gate capping patterns 145.

The first front interlayer insulating film 190 is disposed on the first surface 50_S1 of the first back wiring line 50 and on the first surface of the second back wiring line 60. The first front interlayer insulating film 190 may include at least one of silicon oxide, silicon nitride, silicon oxynitride, and a low-k dielectric material.

A source/drain etching stop film 185 may extend along the profiles of the first source/drain pattern 150 and the second source/drain pattern 160. The source/drain etching stop film 185 may be disposed between the first source/drain pattern 150 and the first front interlayer insulating film 190, and between the second source/drain pattern 160 and the first front interlayer insulating film 190.

The source/drain etching stop film 185 may include at least one of SiN, SiON, SiOCN, SiBN, SiOBN, SiOC, and a combination thereof.

The first back source/drain contact 170 may extend in the third direction Z. The first back source/drain contact 170 may be connected to the first source/drain pattern 150. For example, the first back source/drain contact 170 may be electrically connected to the first source/drain pattern 150.

The first back source/drain contact 170 may be disposed between the first source/drain pattern 150 and the first back wiring line 50. The first back source/drain contact 170 may overlap with the first back wiring line 50 and the first source/drain pattern 150 in the third direction Z.

The first back source/drain contact 170 connects the first source/drain pattern 150 and the first back wiring line 50. The first back source/drain contact 170 may be connected to the first back wiring line 50. The first back source/drain contact 170 may be connected to the first surface 50_S1 of the first back wiring line 50.

The first back source/drain contact 170 may be disposed within the back insert insulating film 291. The first back source/drain contact 170 may extend from the first surface 50_S1 of the first back wiring line 50 to the first source/drain pattern 150.

The first back source/drain contact 170 may have a first surface 170_S1 and a second surface 170_S2 that are opposite to each other in the third direction Z. The first back source/drain contact 170 may have sidewalls 170SW that connect the first surface 170_S1 and the second surface 170_S2. For example, the first surface 170_S1 of the first back source/drain contact 170 may be the upper surface of the first back source/drain contact 170. The second surface 170_S2 of the first back source/drain contact 170 may be the bottom surface of the first back source/drain contact 170.

The first surface 170_S1 of the first back source/drain contact 170 may face the first source/drain pattern 150. The first surface 170_S1 of the first back source/drain contact 170 may be connected to the first source/drain pattern 150. For example, the first surface 170_S1 of the first back source/drain contact 170 may be the interface between the first back source/drain contact 170 and the back contact silicide film 155. The first surface 170_S1 of the first back source/drain contact 170 may be a connecting surface in contact with the back contact silicide film 155. The first surface 170_S1 of the first back source/drain contact 170 may be a connecting surface of the first back source/drain contact 170.

The second surface 170_S2 of the first back source/drain contact 170 may face the first back wiring line 50. The second surface 170_S2 of the first back source/drain contact 170 may be connected to the first back wiring line 50.

The sidewalls 170SW of the first back source/drain contact 170 may extend in the third direction Z. The back insert insulating film 291 may be disposed on the sidewalls 170SW of the first back source/drain contact 170. The back insert insulating film 291 may cover the sidewalls 170SW of the first back source/drain contact 170. In FIG. 4, the back insert insulating film 291 is illustrated as not being disposed between the first back source/drain contact 170 and the field insulating film 105, but the present disclosure is not limited thereto. Alternatively, the back insert insulating film 291 may be disposed on the sidewalls 170SW of the first back source/drain contact 170.

In a cross-sectional view such as FIG. 4, the first back source/drain contact 170 may contact the source/drain etching stop film 185. The source/drain etching stop film 185 may contact portions of the sidewalls 170SW of the first back source/drain contact 170. A part of the first back source/drain contact 170 may be recessed into the first front interlayer insulating film 190.

The shape of the first surface 170_S1 of the first back source/drain contact 170 will hereinafter be described.

The first surface 170_S1 of the first back source/drain contact 170 may have a 3D saddle structure.

The first surface 170_S1 of the first back source/drain contact 170 may include a saddle point SP, a first saddle region SR1, and a second saddle region SR2. The first saddle region SR1 may be located in the first direction X from the saddle point SP. The first saddle region SR1 may extend in the third direction Z toward the first back wiring line 50. The second saddle region SR2 may be located in the second direction Y from the saddle point SP. The second saddle region SR2 may extend in the third direction Z away from the first back wiring line 50.

In a cross-sectional view cut perpendicular to the second direction Y, the first surface 170_S1 of the first back source/drain contact 170 may have a convex shape. For example, in the cross-sectional view cut perpendicular to the second direction Y, the first surface 170_S1 of the first back source/drain contact 170 may have a convex curved shape. In the cross-sectional view cut perpendicular to the second direction Y, the first surface 170_S1 of the first back source/drain contact 170 may have an inverse “U” shape. In the cross-sectional view cut perpendicular to the second direction Y, the saddle point SP of the first surface 170_S1 of the first back source/drain contact 170 may be the point furthest from the first back wiring line 50. The first surface 170_S1 of the first back source/drain contact 170, as illustrated in the cross-sectional view cut perpendicular to the second direction Y, may be the first saddle region SR1.

In a cross-sectional view cut perpendicular to the first direction X, the first surface 170_S1 of the first back source/drain contact 170 may have a concave shape. For example, in the cross-sectional view cut perpendicular to the first direction X, the first surface 170_S1 of the first back source/drain contact 170 may have a concave curved shape. In the cross-sectional view cut perpendicular to the first direction X, the first surface 170_S1 of the first back source/drain contact 170 may have a “U” shape. In the cross-sectional view cut perpendicular to the first direction X, the saddle point SP of the first surface 170_S1 of the first back source/drain contact 170 may be the point closest to the first back wiring line 50. The first surface 170_S1 of the first back source/drain contact 170, as illustrated in the cross-sectional view cut perpendicular to the first direction X, may be the second saddle region SR2.

The first back source/drain contact 170 includes a conductive material. The first back source/drain contact 170 may include, for example, at least one of a metal, conductive metal nitride, conductive metal carbide, conductive metal oxide, conductive metal oxynitride, conductive metal silicon nitride, conductive metal carbonitride, and a 2D material. The first back source/drain contact 170 is illustrated as being a single layer, but the present disclosure is not limited thereto. Alternatively, the first back source/drain contact 170 may have a multilayer conductive structure. The first back source/drain contact 170 may include a back contact barrier film and a back contact filling film.

The back contact silicide film 155 may be disposed between the first back source/drain contact 170 and the first source/drain pattern 150. The back contact silicide film 155 may contact the first back source/drain contact 170 and the first source/drain pattern 150. For example, the back contact silicide film 155 may contact the first semiconductor bottom film 153. The back contact silicide film 155 may include a metal silicide material.

By having a saddle structure, the first surface 170_S1 of the first back source/drain contact 170 can increase the contact area between the first back source/drain contact 170 and the first source/drain pattern 150. This can lower the contact resistance between the first back source/drain contact 170 and the first source/drain pattern 150.

Additionally, the back contact silicide film 155 may contact the first semiconductor bottom film 153, which has a higher impurity concentration than the first semiconductor liners 151. This can lower the contact resistance between the first back source/drain contact 170 and the first source/drain pattern 150.

As a result, the semiconductor device according to some implementations of the present disclosure can have improved performance and reliability.

The shape in which the second back source/drain contact 270 is electrically connected to the source/drain patterns connected with the second sheet patterns NS2 may be similar to that illustrated in FIGS. 2 and 4. The second back source/drain contact 270 may be connected to the second back wiring line 60.

The first front source/drain contact 175 may extend in the third direction Z. The first front source/drain contact 175 may be connected to the second source/drain pattern 160. For example, the first front source/drain contact 175 may be electrically connected to the second source/drain pattern 160.

The first front source/drain contact 175 is disposed on the upper surface of the back insert insulating film 291. The first front source/drain contact 175 may be disposed within the first front interlayer insulating film 190 and the second source/drain pattern 160. Parts of the first front source/drain contact 175 may be disposed within the second source/drain pattern 160.

Each of the first front source/drain contact 175 may have a first surface 175_S1 and a second surface 175_S2 that are opposite to each other in the third direction Z. The second surfaces 175_S2 of the first front source/drain contact 175 may face the second source/drain pattern 160. The second surfaces 175_S2 of the first front source/drain contact 175 are connected to the second source/drain pattern 160.

For example, the second surfaces 175_S2 of the first front source/drain contact 175 may be the interfaces between the first front source/drain contact 175 and a front contact silicide film 165. The second surfaces 175_S2 of the first front source/drain contact 175 may be connecting surfaces in contact with the front contact silicide film 165. The second surfaces 175_S2 of the first front source/drain contact 175 may be connecting surfaces of the first front source/drain contact 175.

The second surfaces 175_S2 of the first front source/drain contact 175 may have a bowl shape. In the cross-sectional view cut perpendicular to the first direction X, the second surfaces 175_S2 of the first front source/drain contact 175 may have a convex shape. In the cross-sectional view cut perpendicular to the second direction Y, the first surfaces 175_S2 of the first front source/drain contact 175 may have a convex shape. For example, in the cross-sectional views cut perpendicular to the first direction X and perpendicular to the second direction Y, the second surfaces 175_S2 of the first front source/drain contact 175 may have a convex curved shape.

The first front source/drain contact 175 are illustrated as having a single conductive film structure, but the present disclosure is not limited thereto. Alternatively, the first front source/drain contact 175 may have a multilayer conductive structure including a front contact barrier film and a front contact filling film.

The first front source/drain contact 175 may include, for example, at least one of a metal, conductive metal nitride, conductive metal carbide, conductive metal oxide, conductive metal carbonitride, and a 2D material.

The shape in which the second front source/drain contact 275 are electrically connected to the source/drain patterns connected with the second sheet patterns NS2 may be similar to that illustrated in FIGS. 2 and 5.

The front contact silicide film 165 may be disposed between the first front source/drain contact 175 and the second source/drain pattern 160. The front contact silicide film 165 contacts the first front source/drain contact 175. The front contact silicide film 165 may include a metal silicide material.

The second front interlayer insulating film 191 may be disposed on the first front interlayer insulating film 190, the gate structures GS, and the first front source/drain contact 175. The second front interlayer insulating film 191 may be disposed on the second front source/drain contact 275. The second front interlayer insulating film 191 may include, for example, at least one of silicon oxide, silicon nitride, silicon carbonitride, silicon oxynitride, and a low-k material.

The front wiring structure 195 may be disposed within the second front interlayer insulating film 191. The front wiring structure 195 is disposed on the first surface 50_S1 of the first back wiring line 50 and on the first surface of the second back wiring line 60. The front wiring structure 195 may include a front via plug 196 and a front wiring line 197.

The front wiring structure 195 may be connected to the first front source/drain contact 175. The front wiring structure 195 may be connected to the first surfaces 175_S1 of the first front source/drain contact 175.

The first front source/drain contact 175 may be disposed between the front wiring structure 195 and the second source/drain pattern 160. The first front source/drain contact 175 may connect the front wiring structure 195 and the second source/drain pattern 160. The first front source/drain contact 175 may be connected to the front wiring line 197. For example, the front wiring structure 195 may not be connected to the first source/drain pattern 150 connected to the first back source/drain contact 170.

The front wiring structure 195 may be connected to the first source/drain pattern 150 through other front source/drain contacts. That is, the front wiring structure 195 may be connected to the first back source/drain contact 170 via the first source/drain pattern 150.

The front via plug 196 and the front wiring line 197 may each include, for example, at least one of metal, conductive metal nitride, conductive metal carbide, conductive metal oxide, conductive metal carbonitride, and two-dimensional materials.

The front via plug 196 and the front wiring line 197 are illustrated as having a single conductive film structure, but the present disclosure is not limited thereto. Alternatively, for example, at least one of the front via plug 196 and the front wiring line 197 may have a multilayer conductive structure. In yet another alternative, the front wiring structure 195 may have an integral structure with no distinct boundary between the front via plug 196 and the front wiring line 197.

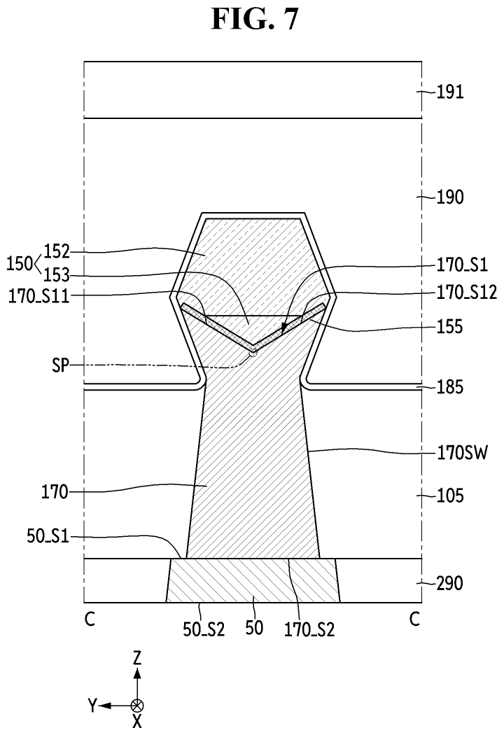

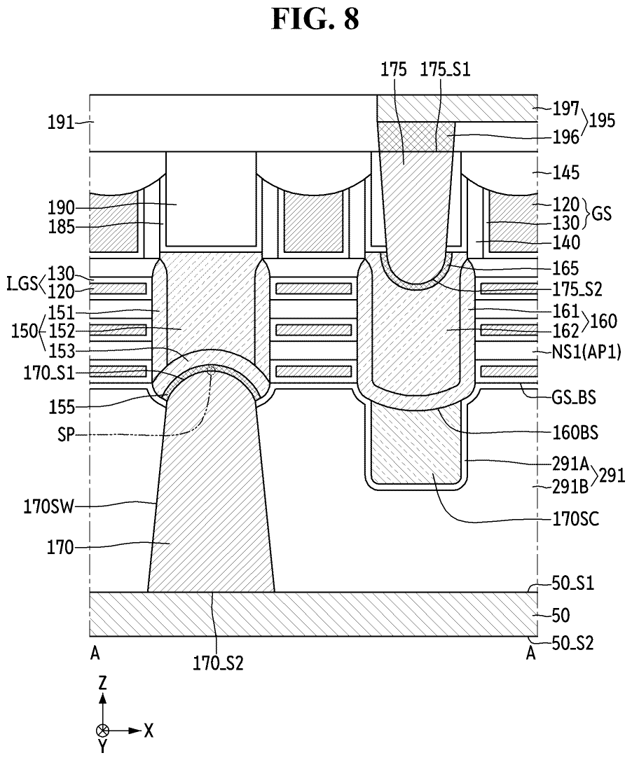

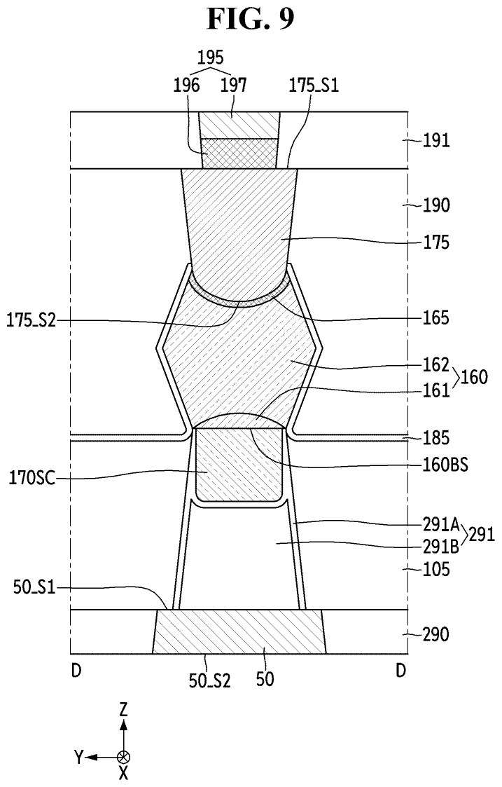

FIG. 7 is diagram for explaining semiconductor device according to some implementations of the present disclosure. FIGS. 8 and 9 are diagrams for explaining semiconductor device according to some implementations of the present disclosure. For convenience of explanation, the implementation of FIGS. 7 to 9 will hereinafter be described, focusing mainly on the differences from what has been explained above with reference to FIGS. 1 to 6.

Referring to FIG. 7, in a cross-sectional view cut perpendicular to the first direction X, the first surface 170_S1 of the first back source/drain contact 170 may include a first inclined surface 170_S11 and a second inclined surface 170_S12.

The first inclined surface 170_S11 and the second inclined surface 170_S12 may be inclined with respect to the third direction Z. Additionally, the first inclined surface 170_S11 and the second inclined surface 170_S12 may be inclined with respect to the second direction Y. In the cross-sectional view cut perpendicular to the first direction X, the first inclined surface 170_S11 and the second inclined surface 170_S12 may be flat.

In the cross-sectional view cut perpendicular to the first direction X, the first surface 170_S1 of the first back source/drain contact may not have a concave curved shape.

Referring to FIGS. 8 and 9, the semiconductor device according to some implementations of the present disclosure may further include a sacrificial epitaxial pattern 170SC, which is disposed between a first back wiring line 50 and a second source/drain pattern 160.

The sacrificial epitaxial pattern 170SC may be disposed within a back insert insulating film 291. The sacrificial epitaxial pattern 170SC may contact the back insert insulating film 291.

The sacrificial epitaxial pattern 170SC may be disposed below a source/drain pattern not connected to the first back source/drain contact 170 or the second back source/drain contact 270. The second source/drain pattern 160 may be disposed on the sacrificial epitaxial pattern 170SC. The sacrificial epitaxial pattern 170SC may overlap with the second source/drain pattern 160 in the third direction Z.

The sacrificial epitaxial pattern 170SC may overlap with the first back source/drain contact 170 in the first direction X. The back insert insulating film 291 may separate the sacrificial epitaxial pattern 170SC and the first back source/drain contact 170.

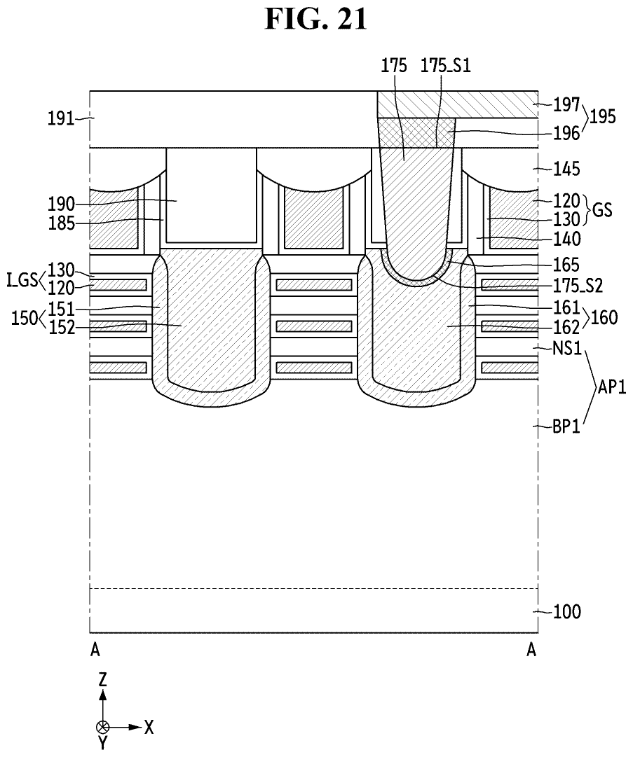

The sacrificial epitaxial pattern 170SC may include a material having an etch selectivity with respect to a first lower pattern (“BP1” in FIG. 21). The sacrificial epitaxial pattern 170SC may include a semiconductor material.

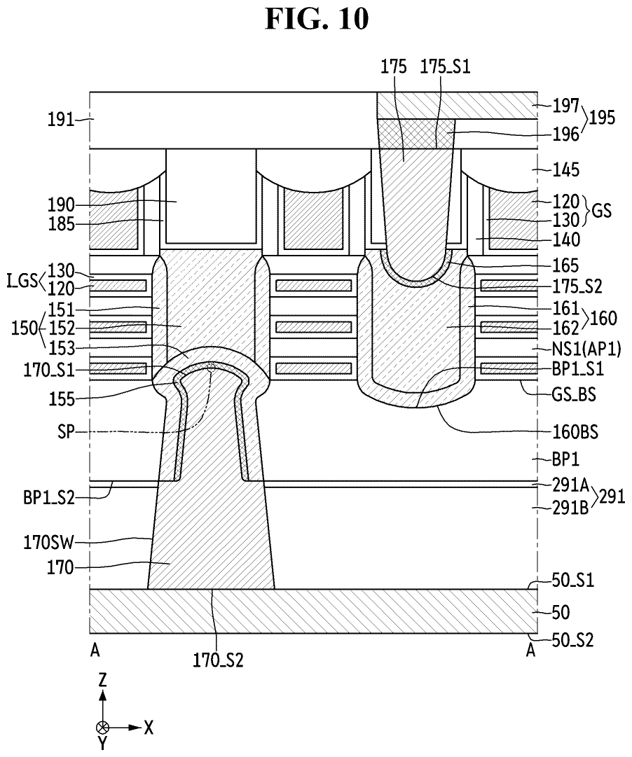

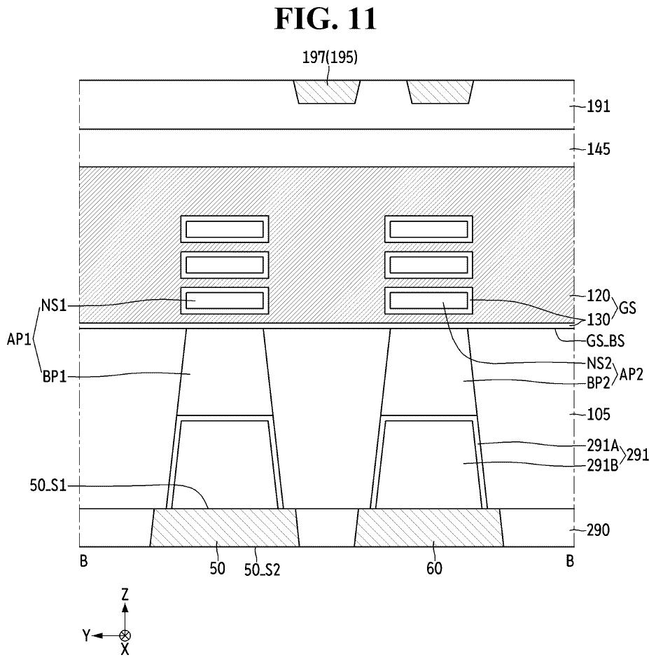

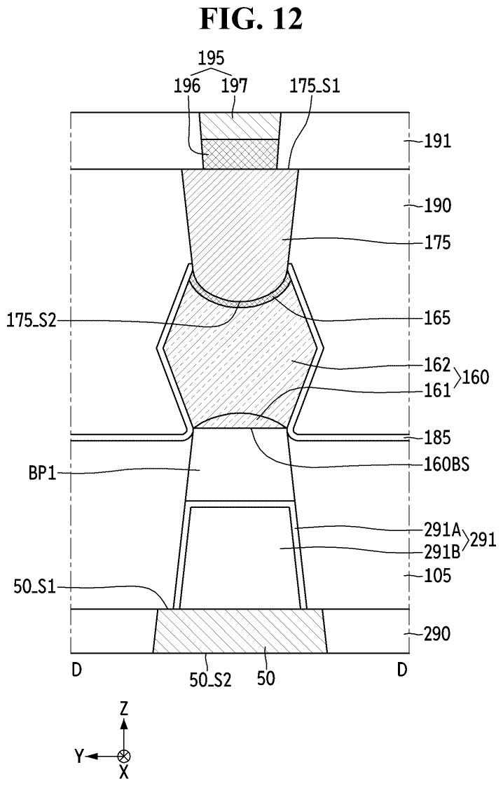

FIGS. 10 to 12 are diagrams for explaining semiconductor device according to some implementations of the present disclosure. For convenience of explanation, the implementation of FIGS. 10 to 12 will hereinafter be described, focusing mainly on the differences from what has been described above with reference to FIGS. 1 to 6.

Referring to FIGS. 10 to 12, in the semiconductor device according to some implementations of the present disclosure, the first active pattern AP1 may include a first fin-shaped pattern BP1 and first sheet patterns NS1, and a second active pattern AP2 may include a second fin-shaped pattern BP2 and second sheet patterns NS2.

The first fin-shaped pattern BP1 and the second fin-shaped pattern BP2 may be disposed on the first surface 50_S1 of the first back wiring line 50 and the first surface of the second back wiring line 60, respectively. The back insert insulating film 291 may be disposed between the first fin-shaped pattern BP1 and the back interlayer insulating film 290, and between the second fin-shaped pattern BP2 and the back interlayer insulating film 290. In a cross-sectional view cut perpendicular to the second direction Y, the back insert insulating film 291 may be disposed between the first fin-shaped pattern BP1 and the first back wiring line 50.

The first fin-shaped pattern BP1 may be disposed between the back insert insulating film 291 and the first source/drain pattern 150. The first fin-shaped pattern BP1 may be disposed between the back insert insulating film 291 and the second source/drain pattern 160.

The back insert insulating film 291 and the first fin-shaped pattern BP1 may be disposed on sidewalls 170SW of the first back source/drain contact 170. The back insert insulating film 291 and the first fin-shaped pattern BP1 may cover the sidewalls 170SW of the first back source/drain contact 170.

The first fin-shaped pattern BP1 will hereinafter be described as an example. The first fin-shaped pattern BP1 may include a first surface BP1_S1 and a second surface BP1_S2 that are opposite to each other in the third direction Z. The first surface BP1_S1 of the first fin-shaped pattern BP1 may face gate structures GS, the first source/drain pattern 150, and the second source/drain pattern 160. For example, the first surface BP1_S1 of the first fin-shaped pattern BP1 may contact bottom surfaces GS_BS of the gate structures GS. The first surface BP1_S1 of the first fin-shaped pattern BP1 may contact the bottom surface of the first source/drain pattern 150 and a bottom surface 160BS of the second source/drain pattern 160.

The second surface BP1_S2 of the first fin-shaped pattern BP1 may face the back insert insulating film 291. For example, the second surface BP1_S2 of the first fin-shaped pattern may contact the back insert insulating film 291. The first fin-shaped pattern BP1 may contact the upper surface of the back insert insulating film 291. The first back wiring line 50 and the second back wiring line 60 may be disposed on the second surface BP1_S2 of the first fin-shaped pattern BP1.

The first sheet patterns NS1 may be disposed on the first fin-shaped pattern BP1. The first sheet patterns NS1 may be disposed on the first surface BP1_S1 of the first fin-shaped pattern BP1. In other words, the first fin-shaped pattern BP1 may be disposed between the first sheet patterns NS1 and the back insert insulating film 291.

The second sheet patterns NS2 may be disposed on the second fin-shaped pattern BP2. The second fin-shaped pattern BP2 may be disposed between the second sheet patterns NS2 and the back insert insulating film 291.

The first fin-shaped pattern BP1 and the second fin-shaped pattern BP2 may each include an elemental semiconductor material such as Si or Ge. Alternatively, the first fin-shaped pattern BP1 and the second fin-shaped pattern BP2 may each include a compound semiconductor, for example, a Group IV-IV compound semiconductor or a Group III-V compound semiconductor.

The first semiconductor bottom film 153 may be disposed between the first fin-shaped pattern BP1 and the first back source/drain contact 170. For example, the first semiconductor bottom film 153 may protrude in the third direction Z from the first surface BP1_S1 of the first fin-shaped pattern BP1. The first semiconductor bottom film 153 may extend to the second surface BP1_S2 of the first fin-shaped pattern BP1. The first semiconductor bottom film 153 may extend along parts of the sidewalls 170SW of the first back source/drain contact 170.

The interface between the first back source/drain contact 170 and the back contact silicide film 155 may include the first surface 170_S1 of the first back source/drain contact 170 and parts of the sidewalls 170SW of the first back source/drain contact 170.

Alternatively, the first semiconductor bottom film 153 may not be disposed between the first fin-shaped pattern BP1 and the first back source/drain contact 170. For example, if the entire first semiconductor bottom film 153 is converted to a metal silicide material during a silicide process, the first semiconductor bottom film 153 may not remain on the sidewalls 170SW of the first back source/drain contact 170.

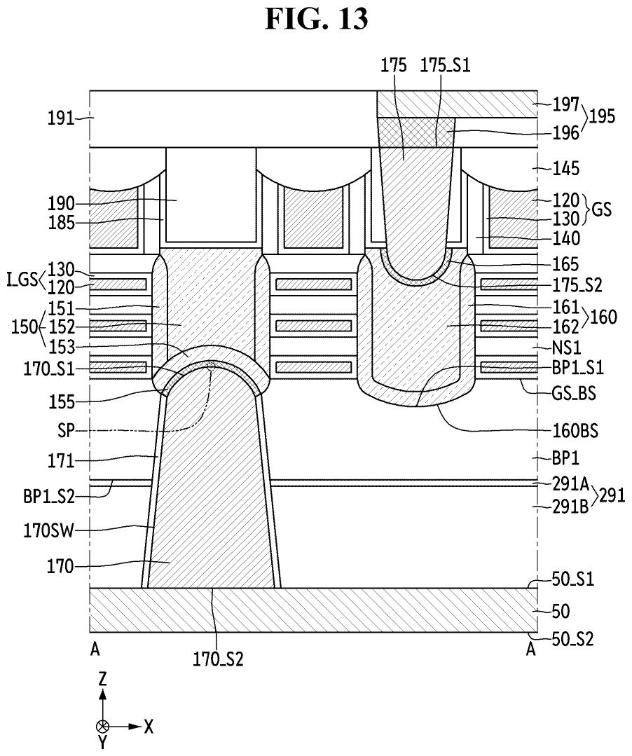

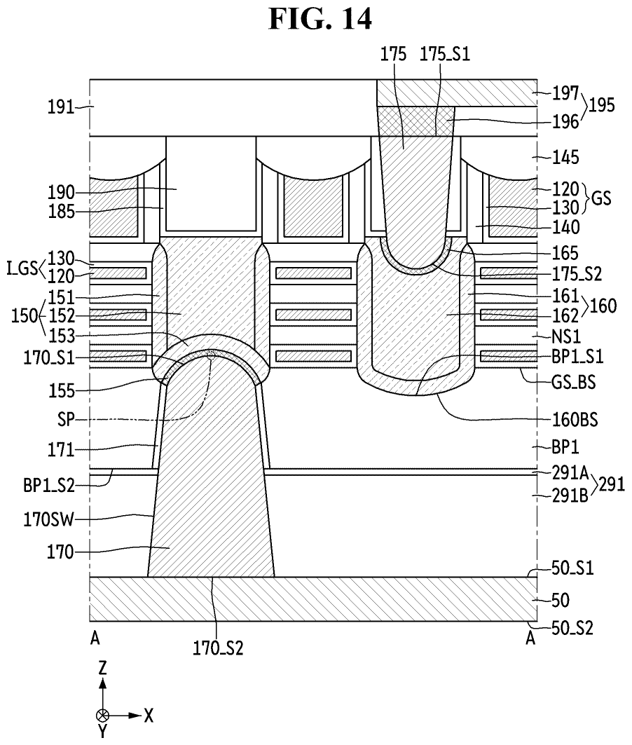

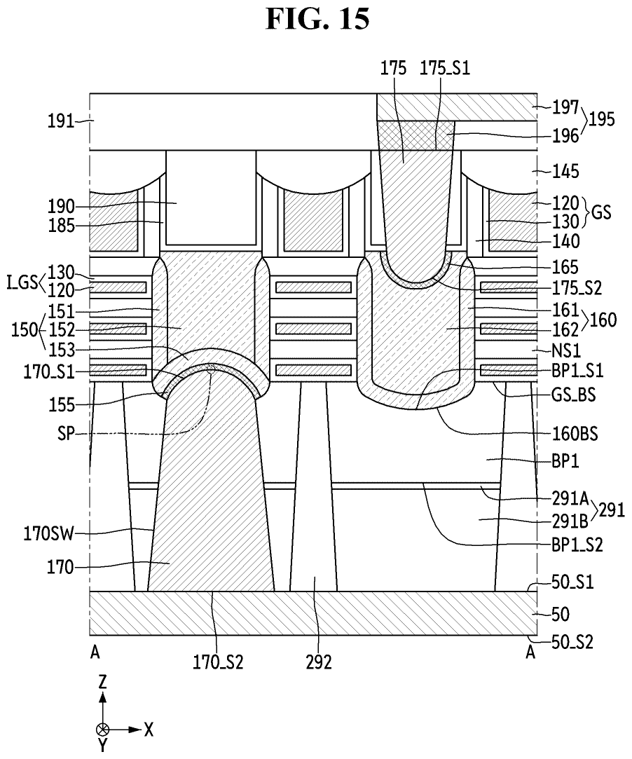

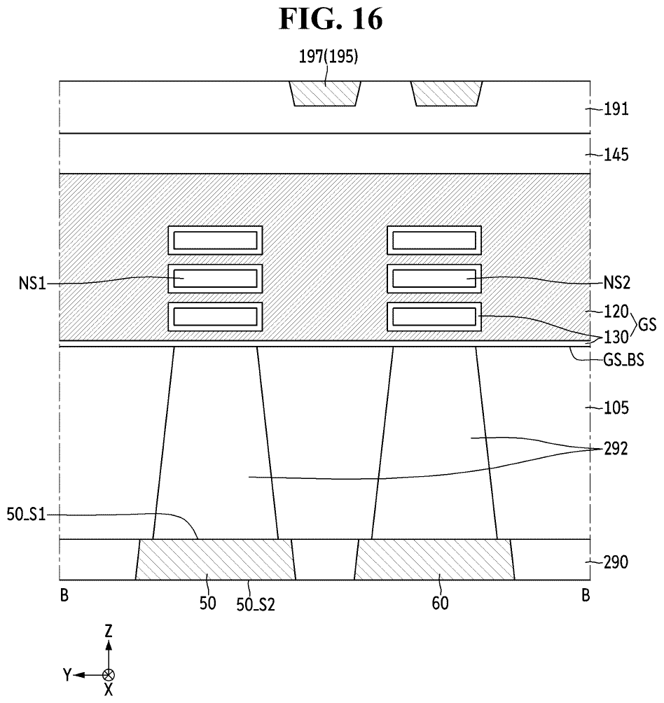

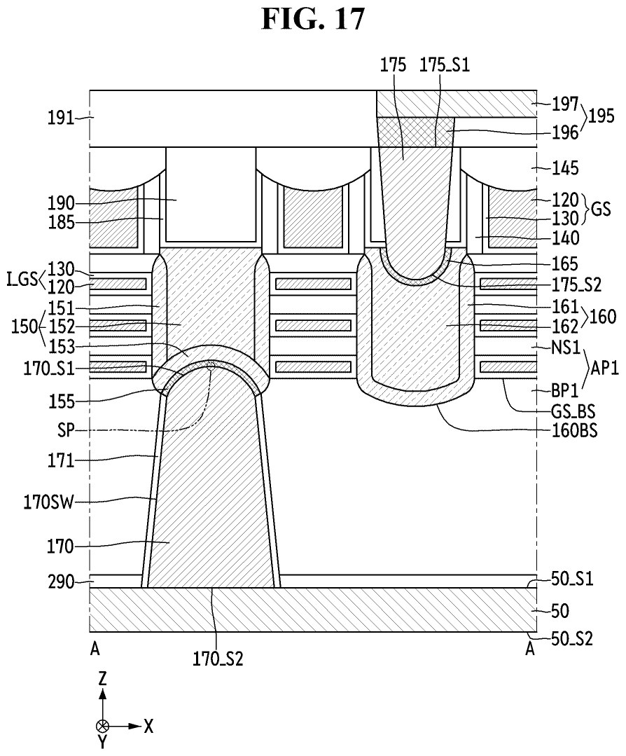

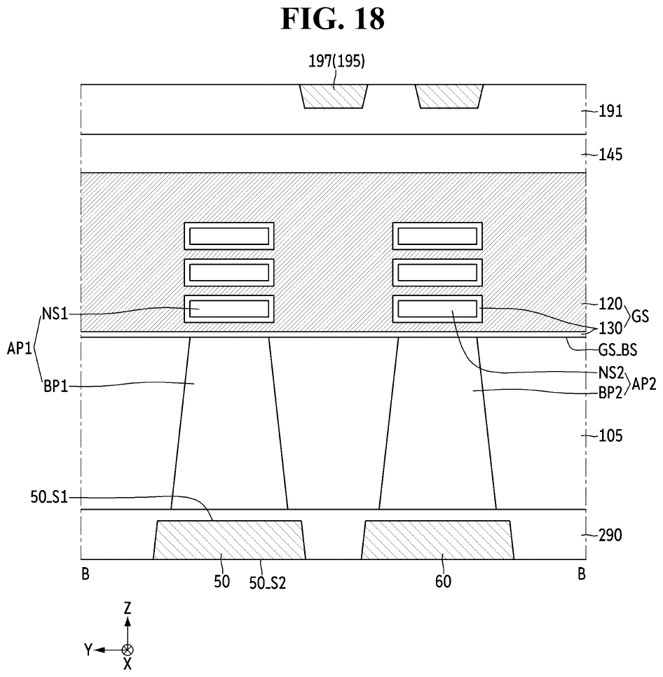

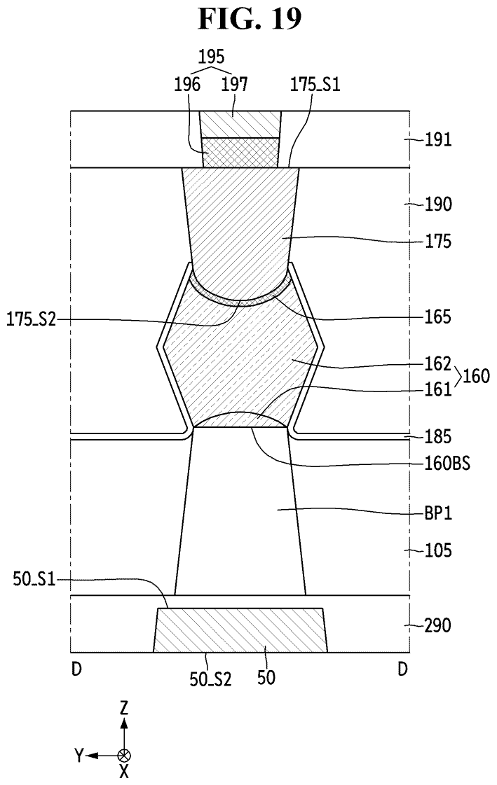

FIGS. 13 and 14 are diagrams for explaining semiconductor device according to some implementations of the present disclosure. FIGS. 15 and 16 are diagrams for explaining semiconductor device according to some implementations of the present disclosure. FIGS. 17 to 19 are diagrams for explaining semiconductor device according to some implementations of the present disclosure. For convenience of explanation, the implementations of FIGS. 13 to 19 will hereinafter be described, focusing mainly on the differences from what has been described above with reference to FIGS. 1 to 6 and 10 to 12.

Referring to FIGS. 13 and 14, each of the semiconductor devices according to some implementations of the present disclosure may further include a back contact insulating liner 171, which is disposed between the first fin-shaped pattern BP1 and the first back source/drain contact 170.

The back contact insulating liner 171 may extend along sidewalls 170SW of the first back source/drain contact 170. The back contact insulating liner 171 may include an insulating material.

Due to the presence of the back contact insulating liner 171, the first semiconductor bottom film 153 may not be disposed between the first fin-shaped pattern BP1 and the first back source/drain contact 170. The first semiconductor bottom film 153 may not protrude in a third direction Z from the first surface BP1_S1 of the first fin-shaped pattern BP1.

In FIGS. 13 and 14, the back contact insulating liner 171 may be disposed between the first back source/drain contact 170 and the first fin-shaped pattern BP1.

In FIG. 13, the back contact insulating liner 171 may be disposed between the first back source/drain contact 170 and the back insert insulating film 291. Conversely, in FIG. 14, the back contact insulating liner 171 is not disposed between the first back source/drain contact 170 and the back insert insulating film 291.

Referring to FIGS. 15 and 16, the semiconductor device according to some implementations of the present disclosure may further include an active region insulating pattern 292, which penetrates a first fin-shaped pattern BP1.

The active region insulating pattern 292 may extend in the third direction Z. The active region insulating pattern 292 may overlap with gate structures GS in the third direction Z.

For example, the active region insulating pattern 292 may divide the first fin-shaped pattern BP1. The active region insulating pattern 292 may penetrate the first fin-shaped pattern BP1 and the back insert insulating film 291. The active region insulating pattern 292 may contact the gate structures GS. The active region insulating pattern 292 may contact bottom surfaces GS_BS of the gate structure GS. The active region insulating pattern 292 may block a leakage current path that can flow through the first fin-shaped pattern BP1.

The width of the active region insulating pattern 292 in the first direction X may decrease away from a first surface 50_S1 of a first back wiring line 50.

The active region insulating pattern 292 may include an insulating material.

Referring to FIGS. 17 through 19, the semiconductor device according to some implementations of the present disclosure may not include a back insert insulating film (“291” in FIGS. 2 and 3).

For example, a first fin-shaped pattern BP1 may contact a back interlayer insulating film 290. The first back source/drain contact 170 may be disposed within the first fin-shaped pattern BP1 and the back interlayer insulating film 290.

Part of the first back wiring contact 170 may be disposed within the back interlayer insulating film 290. The first back wiring contact 170 may extend from the first surface 50_S1 of the first back wiring line 50 to the first source/drain pattern 150. Alternatively, the back interlayer insulating film 290 may not be disposed between a second surface BP1_S2 of the first fin-shaped pattern BP1 and the first surface 50_S1 of the first back wiring line 50.

The back contact insulating liner 171 may be disposed between the first back source/drain contact 170 and the first fin-shaped pattern BP1. The back contact insulating liner 171 may extend to the second surface 170_S2 of the first back source/drain contact 170. Alternatively, the back contact insulating liner 171 may extend to the boundary between the first fin-shaped pattern BP1 and the back interlayer insulating film 290.

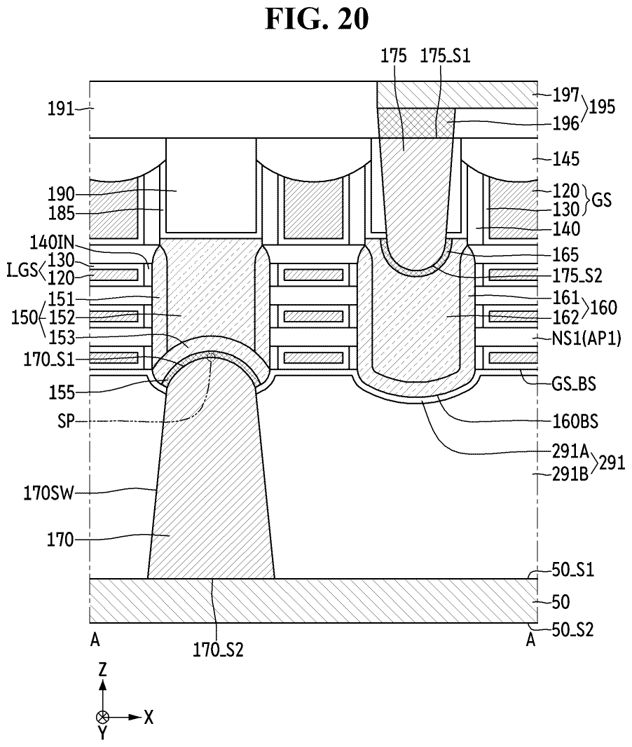

FIG. 20 is diagram for explaining semiconductor device according to some implementations of the present disclosure. For convenience of explanation, the implementation of FIG. 20 will hereinafter be described, focusing mainly on the differences from what has been described above with reference to FIGS. 1 to 6.

Referring to FIG. 20, the semiconductor device according to some implementations of the present disclosure may further include inner spacers 140IN, which are disposed between inner gate structures I_GS and the first source/drain pattern 150.

The inner spacers 140IN may be disposed between the inner gate structures I_GS and the second source/drain pattern 160.

The inner spacers 140IN may be disposed between each pair of adjacent first sheet patterns NS1 in the third direction Z and between the first sheet patterns NS1 and the back insert insulating film 291. The inner spacers 140IN may contact the first source/drain pattern 150 and the second source/drain pattern 160. The inner gate structures I_GS may not contact the first source/drain pattern 150. The inner gate structures I_GS may not contact the second source/drain pattern 160. The inner spacers 140IN may include an insulating material.

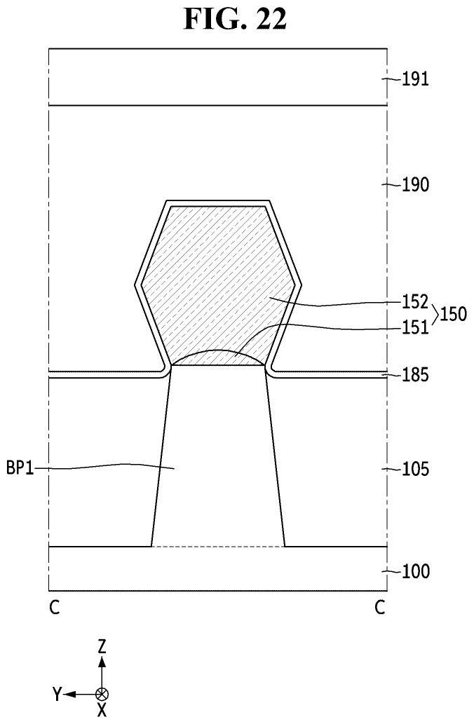

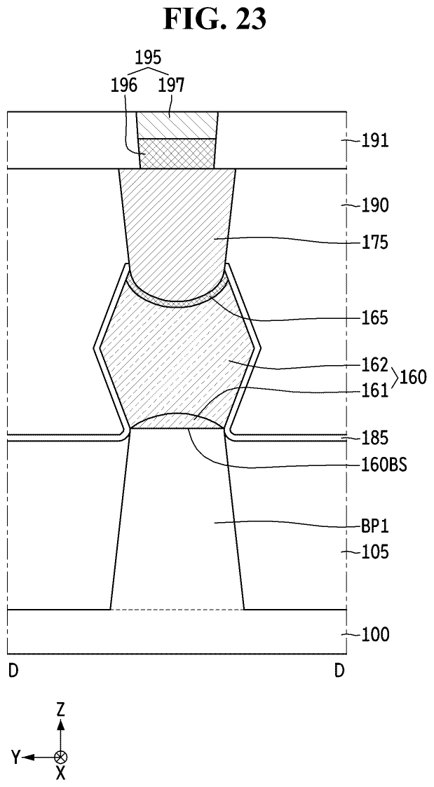

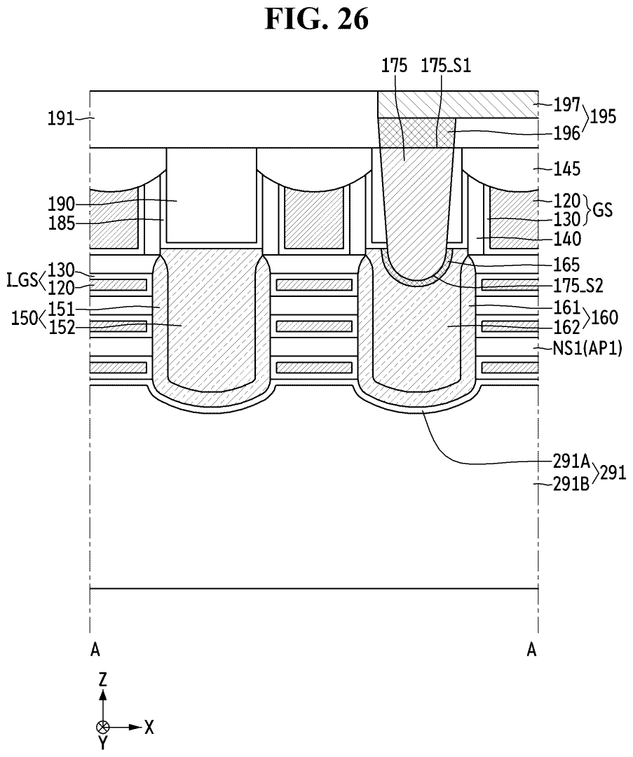

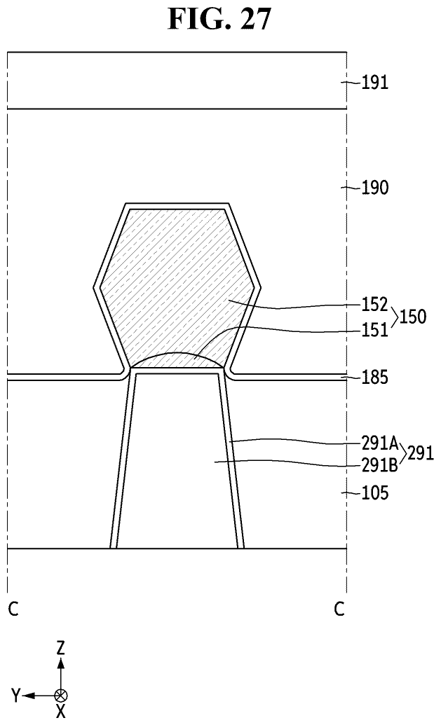

FIGS. 21 to 33 are diagrams for explaining intermediate steps of a method of manufacturing a semiconductor device according to some implementations of the present disclosure. Specifically, FIGS. 27 to 33 illustrate a method of manufacturing the semiconductor device described above with reference to FIGS. 1 to 6.

Referring to FIGS. 21 to 23, a first source/drain pattern 150 and a second source/drain pattern 160 are formed on a first fin-shaped pattern BP1 on a substrate 100.

The substrate 100 may be bulk silicon or silicon-on-insulator (SOI). Alternatively, the substrate 100 may be a silicon substrate or may include other materials such as silicon-germanium (SiGe), SiGe-on-insulator (SGOI), indium antimonide, a lead telluride compound, indium arsenide, indium phosphide, gallium arsenide, or gallium antimonide, but the present disclosure is not limited thereto.

The first active pattern AP1 may be disposed on the upper surface of the substrate 100. The first fin-shaped pattern BP1 may protrude in a third direction Z from the upper surface of the substrate 100.

Before the formation of the first source/drain pattern 150 and the second source/drain pattern 160, gate spacers 140 may be formed on the first fin-shaped pattern BP1.

A first front interlayer insulating film 190 is formed on the first source/drain pattern 150 and the second source/drain pattern 160. The first source/drain pattern 150 may include a first semiconductor liner 151 and a first semiconductor filling film 152. The second source/drain pattern 160 may include a second semiconductor liner 161 and a second semiconductor filling film 162. The first semiconductor liner 151 and the second semiconductor liner 161 are formed simultaneously. The first semiconductor filling film 152 and the second semiconductor filling film 162 are formed simultaneously.

Alternatively, before the formation of the first source/drain pattern 150 and the second source/drain pattern 160, a sacrificial epitaxial pattern (“170SC” in FIGS. 8 and 9) may be formed in the first fin-shaped pattern BP1. The first source/drain pattern 150 and the second source/drain pattern 160 may be formed on the sacrificial epitaxial pattern 170SC.

Thereafter, first sheet patterns NS1 are formed on the first fin-shaped pattern BP1. In this manner, a first active pattern AP1 is formed on the upper surface of the substrate 100.

Thereafter, gate structures GS that surround the first sheet patterns NS1 may be formed on the first fin-shaped pattern BP1. The gate structures GS include a gate insulating film 130 and gate electrodes 120. Gate capping patterns 145 may be formed on the gate electrodes 120. The upper surfaces of the gate capping patterns 145 may be on the same plane as the upper surface of the first front interlayer insulating film 190.

Thereafter, a first front source/drain contact 175 is formed on the upper surface of the substrate 100.

The first front source/drain contact 175 is connected to the second source/drain pattern 160. Before the formation of the first front source/drain contact 175, a front contact silicide film 165 may be formed on the second source/drain pattern 160.

Thereafter, a front wiring structure 195 is formed on the gate structure GS and the first front source/drain contact 175. The front wiring structure 195 may be connected to the first front source/drain contact 175.

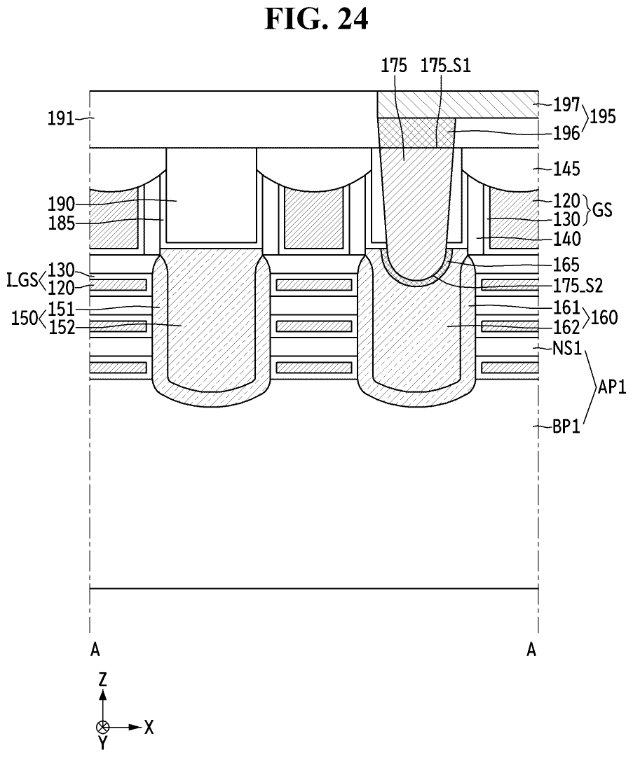

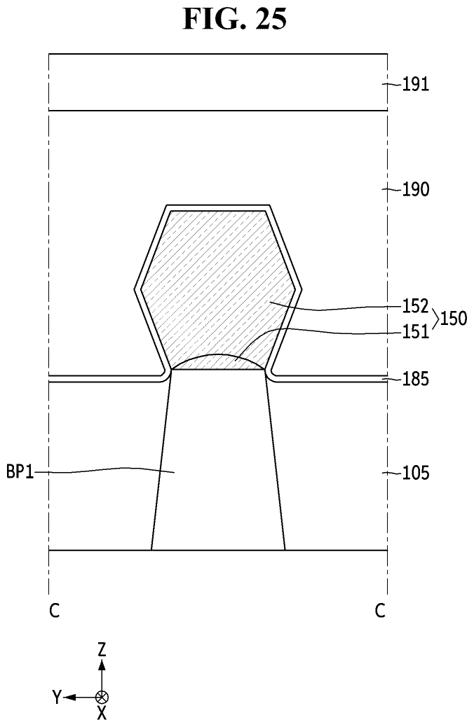

Referring to FIGS. 24 and 25, after the formation of the front wiring structure 195, the substrate 100 may be removed.

As the substrate 100 is removed, the first fin-shaped pattern BP1 and the field insulating film 105 are exposed.

Referring to FIGS. 24 to 27, the first fin-shaped pattern BP1 may be removed.

As the first fin-shaped pattern BP1 is removed, a fin-shaped pattern trench may be formed. The bottom surface of the fin-shaped pattern trench may be defined by the first source/drain pattern 150, the second source/drain pattern 160, and the gate structures GS. The sidewalls of the fin-shaped pattern trench may be defined by the field insulating film 105.

Thereafter, the back insert insulating film 291 may be formed in the fin-shaped pattern trench. The back insert insulating film 291 may fill the fin-shaped pattern trench.

Alternatively, part of the first fin-shaped pattern BP1 may be removed. After the removal of part of the first fin-shaped pattern BP1, the back insert insulating film 291 may be formed in its place.

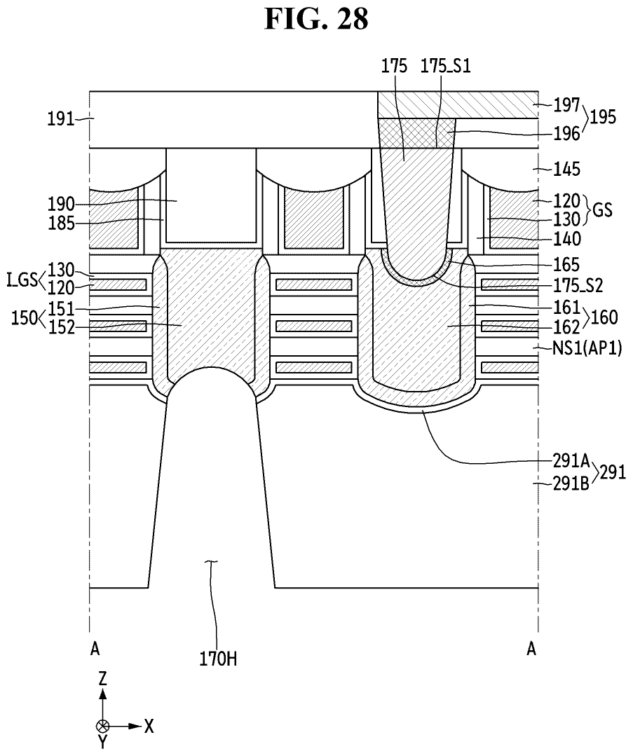

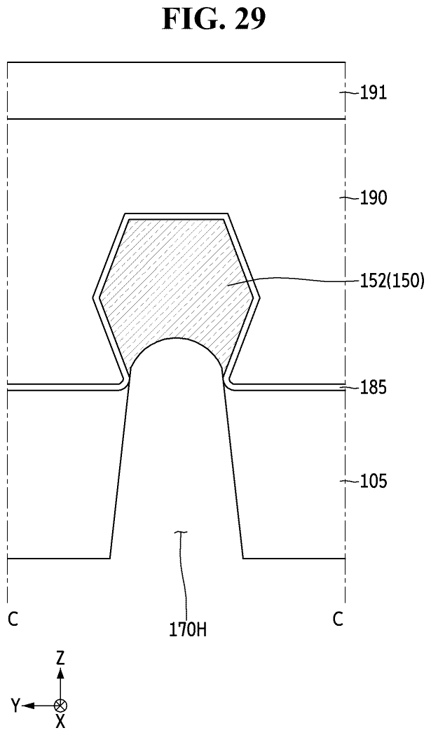

Referring to FIGS. 28 and 29, a back contact hole 170H may be formed in the back insert insulating film 291.

The back contact hole 170H may expose the first source/drain pattern 150. During the formation of the back contact hole 170H, part of the first semiconductor liner 151 may be removed.

In FIG. 29, the back contact hole 170H may not expose a source/drain etching stopper film 185 extending along the sidewalls of the first source/drain pattern 150. Alternatively, part of the source/drain etching stopper film 185 extending along the sidewalls of the first source/drain pattern 150 may be exposed by the back contact hole 170H.

Referring to FIGS. 28 to 31, the first source/drain pattern 150 may be further etched to form a back contact hole extension 170H_E.

The back contact hole extension 170H_E may be formed using, for example, an isotropic etching process.

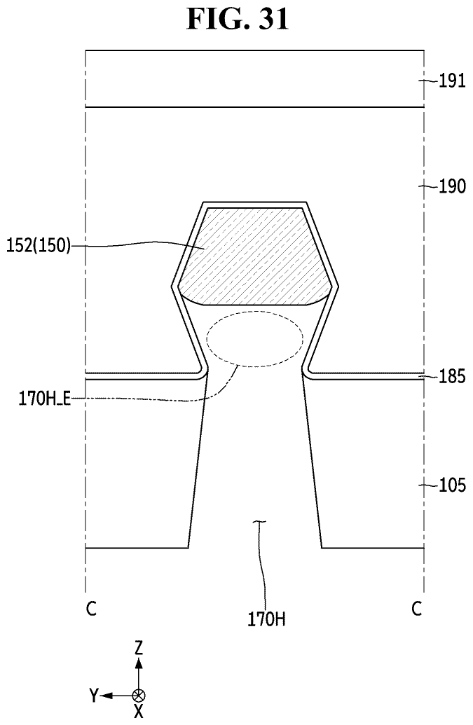

In FIG. 31, the back contact hole extension 170H_E may expose the source/drain etching stopper film 185 extending along the sidewalls of the first source/drain pattern 150.

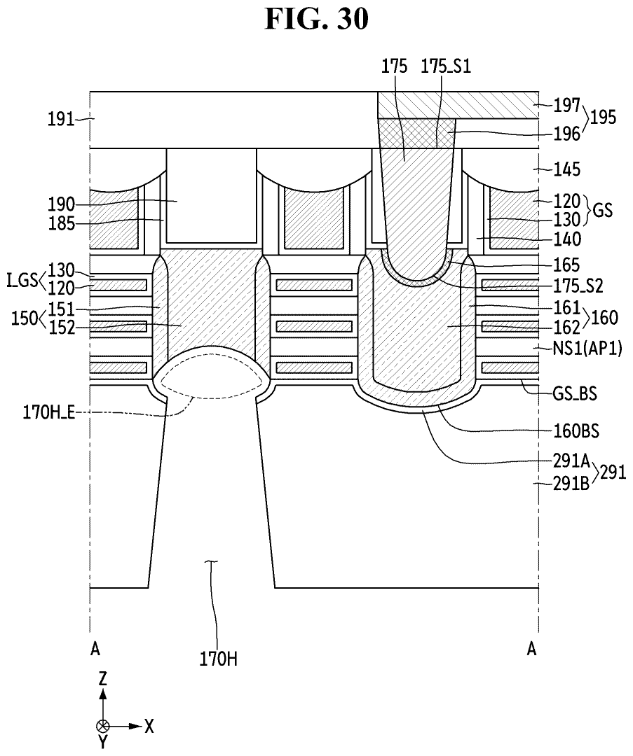

Referring to FIGS. 30 to 33, a first semiconductor bottom film 153 may be formed in the back contact hole extension 170H_E.

The first semiconductor bottom film 153 may be formed in the back contact hole 170H. For example, the first semiconductor bottom film 153 may be formed using an epitaxial growth method.

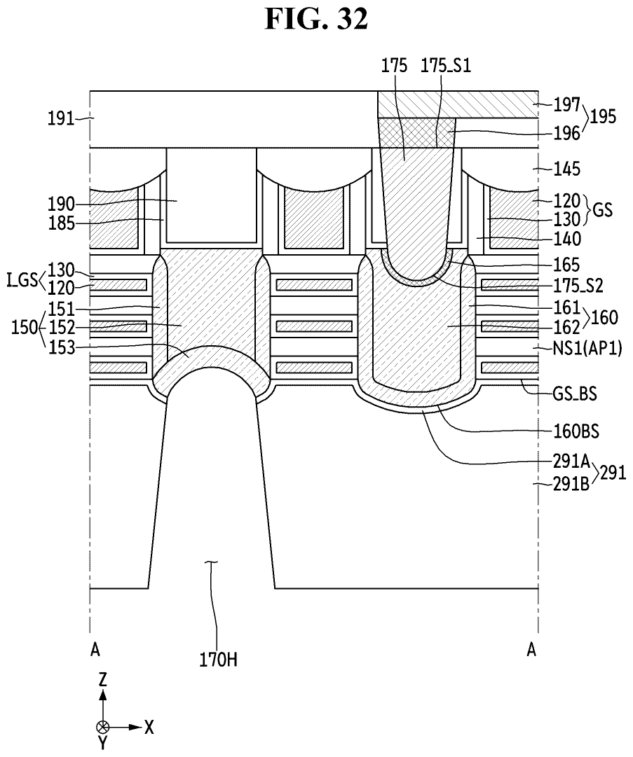

In FIG. 32, the first semiconductor bottom film 153 may be formed along the profile of the first semiconductor liner 151 and the first semiconductor filling film 152 exposed by the back contact hole 170H. The surface of the first semiconductor bottom film 153 exposed by the back contact hole 170H may have a concave shape.

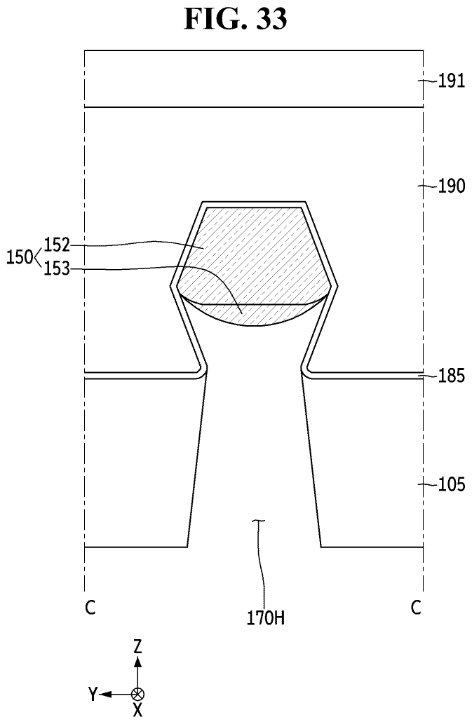

In FIG. 33, the first semiconductor bottom film 153 may not grow well on the source/drain etching stopper film 185. Consequently, the surface of the first semiconductor bottom film 153 exposed by the back contact hole 170H may have a convex shape.

Thereafter, referring to FIGS. 2 and 4, a back contact silicide film 155 may be formed along the surface of the first semiconductor bottom film 153 exposed by the back contact hole 170H. A first back source/drain contact 170 may be formed on the back contact silicide film 155. The first back source/drain contact 170 may fill the back contact hole 170H. A first back wiring line 50 may be formed on the first back source/drain contact 170.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In concluding the detailed description, those skilled in the art will appreciate that many variations and modifications may be made to the preferred implementations without substantially departing from the principles of the present disclosure. Therefore, the disclosed preferred implementations of the disclosure are used in a generic and descriptive sense only and not for purposes of limitation.

What is claimed is:

1. A semiconductor device comprising:
a back interlayer insulating film;
a back wiring line within the back interlayer insulating film, and including a first surface and a second surface that are opposite to each other in a first direction;
a first source/drain pattern on the first surface of the back wiring line;
a second source/drain pattern on the first surface of the back wiring line and spaced apart from the first source/drain pattern in a second direction that is different from the first direction; and
a back source/drain contact between the first source/drain pattern and the back wiring line, wherein the back source/drain contact is connected to the first source/drain pattern and overlaps with the first source/drain pattern in the first direction,
wherein the back source/drain contact includes a first surface that is connected to the first source/drain pattern and a second surface that is opposite to the first surface in the first direction,
wherein the first surface of the back source/drain contact has a convex shape extending along the second direction, and
wherein the first surface of the back source/drain contact has a concave shape extending along a third direction that is different from the first and second directions.

2. The semiconductor device of claim 1,
wherein the first surface of the back source/drain contact has a convex curved shape extending along the second direction, and
wherein the first surface of the back source/drain contact has a concave curved shape extending along the third direction.

3. The semiconductor device of claim 1,
wherein the first surface of the back source/drain contact has a convex curved shape extending along the second direction,
wherein, along the third direction, the first surface of the back source/drain contact includes a first inclined surface and a second inclined surface that are inclined with respect to the first direction, and
each of the first and second inclined surfaces is planar.

4. The semiconductor device of claim 1, further comprising:
a back insert insulating film between the back interlayer insulating film and the second source/drain pattern; and
a gate structure extending in the third direction and between the first source/drain pattern and the second source/drain pattern,
wherein the back insert insulating film is on sidewalls of the back source/drain contact.

5. The semiconductor device of claim 4,
wherein the back insert insulating film is in contact with the gate structure.

6. The semiconductor device of claim 4, further comprising:
a fin-shaped pattern between the back insert insulating film and the second source/drain pattern,
wherein the fin-shaped pattern and the back insert insulating film cover the sidewalls of the back source/drain contact.

7. The semiconductor device of claim 6, further comprising:
a back contact insulating liner between the fin-shaped pattern and the back source/drain contact,
wherein the back contact insulating liner extends along the sidewalls of the back source/drain contact.

8. The semiconductor device of claim 6, further comprising:
an active region insulating pattern penetrating the back insert insulating film and the fin-shaped pattern, and extending in the first direction,
wherein the active region insulating pattern overlaps with the gate structure in the first direction.

9. The semiconductor device of claim 1, further comprising:
a sacrificial epitaxial pattern between the second source/drain pattern and the back wiring line.

10. The semiconductor device of claim 1, further comprising:
a front wiring line on the first and second source/drain patterns and connected to the second source/drain pattern; and
a front source/drain contact between the front wiring line and the second source/drain pattern,
wherein the front source/drain contact includes a connection surface connected to the second source/drain pattern, and
wherein the connection surface of the front source/drain contact has a convex shape extending along the second direction and along the third direction.

11. A semiconductor device comprising:
a back interlayer insulating film;
a back wiring line within the back interlayer insulating film, and including a first surface and a second surface that are opposite to each other in a first direction;
a first source/drain pattern on the first surface of the back wiring line;
a second source/drain pattern on the first surface of the back wiring line and spaced apart from the first source/drain pattern in a second direction; and
a back source/drain contact between the first source/drain pattern and the back wiring line, wherein the back source/drain contact is connected to the first source/drain pattern and overlaps with the first source/drain pattern in the first direction,
wherein the back source/drain contact includes a first surface that is connected to the first source/drain pattern and a second surface that is opposite to the first surface in the first direction, and
the first surface of the back source/drain contact includes a saddle point.

12. The semiconductor device of claim 11,
wherein the saddle point is a point, on the first surface of the back source/drain contact along the second direction, that is furthest from the back wiring line, and
wherein the saddle point is also a point, on the first surface of the back source/drain contact along a third direction, that is closest to the back wiring line, wherein the third direction is different from the first direction and from the second direction.

13. The semiconductor device of claim 11, further comprising:
a back insert insulating film between the back interlayer insulating film and the second source/drain pattern; and
a gate structure extending in a third direction and between the first source/drain pattern and the second source/drain pattern,
wherein the back insert insulating film is in contact with the back source/drain contact and the gate structure.

14. The semiconductor device of claim 11, further comprising:
a back insert insulating film between the back interlayer insulating film and the second source/drain pattern;
a gate structure extending in a third direction and between the first source/drain pattern and the second source/drain pattern; and
a fin-shaped pattern between the back insert insulating film and the second source/drain pattern.

15. The semiconductor device of claim 14, further comprising:
a back contact insulating liner between the fin-shaped pattern and the back source/drain contact,
wherein the back contact insulating liner extends along sidewalls of the back source/drain contact.

16. The semiconductor device of claim 14, further comprising:
an active region insulating pattern overlapping with the gate structure in the first direction and extending in the first direction,
wherein the active region insulating pattern is in contact with the gate structure.

17. The semiconductor device of claim 11, further comprising:
a back insert insulating film between the back interlayer insulating film and the second source/drain pattern; and
a sacrificial epitaxial pattern between the second source/drain pattern and the back wiring line,
wherein the sacrificial epitaxial pattern is within a region defined by the back insert insulating film.

18. A semiconductor device comprising:
a back interlayer insulating film;
a back wiring line within the back interlayer insulating film, wherein the back wiring line comprises a first surface and a second surface that are opposite to each other in a first direction;
a first source/drain pattern on the first surface of the back wiring line;
a second source/drain pattern on the first surface of the back wiring line and spaced apart from the first source/drain pattern in a second direction, wherein the second direction is different from the first direction;
a plurality of sheet patterns connected to the first source/drain pattern and the second source/drain pattern;
a gate electrode surrounding the plurality of sheet patterns and extending in a third direction;
a back source/drain contact between the first source/drain pattern and the back wiring line and connected to the first source/drain pattern; and
a back contact silicide film between the back source/drain contact and the first source/drain pattern,
wherein the back source/drain contact includes a connection surface in contact with the back contact silicide film, and
the connection surface of the back source/drain contact has a three-dimensional saddle structure.

19. The semiconductor device of claim 18,
wherein the connection surface of the back source/drain contact has a convex curved shape extending along the second direction, and
wherein the connection surface of the back source/drain contact has a concave curved shape extending along the second direction.

20. The semiconductor device of claim 18, further comprising:
a sacrificial epitaxial pattern between the second source/drain pattern and the back wiring line.
